(19) United States
(12) Patent Application Publication
(10) Pub. No.: US 2026/0040767 A1
(43) Pub. Date: Feb. 5, 2026

(54) DISPLAY DEVICE

(71) Applicant: LG Display Co., Ltd., Seoul (KR)

(72) Inventors: Jungdoo JIN, Paju-si (KR); Bangju PARK, Paju-si (KR); Junghan PARK, Paju-si (KR); Sungki HONG, Paju-si (KR); Hyunseok GO, Paju-si (KR)

(73) Assignee: LG Display Co., Ltd., Seoul (KR)

(21) Appl. No.: 19/244,949

(22) Filed: Jun. 20, 2025

(30) Foreign Application Priority Data
Aug. 5, 2024 (KR) 10-2024-0103933

(51) Int. Cl. H10K 59/122; H10K 59/80

(52) U.S. Cl. CPC H10K 59/122; H10K 59/80515; H10K 59/8792

(57) ABSTRACT

A display device includes a substrate including a display area having sub-pixels and a non-display area adjacent to the display area, an anode electrode disposed in each of the sub-pixels on the substrate, a bank disposed on the anode electrode which is located at a boundary between adjacent sub-pixels, covers a periphery of an upper surface of the anode electrode, and includes a first bank on the anode electrode and a second bank on the first bank, and an organic layer disposed on the anode electrode and the bank and disposed across the sub-pixels.

### CROSS-REFERENCE TO RELATED APPLICATION

The present application claims priority to Korean Patent Application No. 10-2024-0103933, filed in the Republic of Korea on Aug. 5, 2024, the entire contents of which is hereby expressly incorporated by reference as if fully set forth herein into the present application.

### BACKGROUND

### Technical Field

The present disclosure relates to a display device, and more specifically, for example, without limitation, to a display device in which it is possible to improve spreadability of a second encapsulation layer.

### Description of the Related Art

As the information society develops, various demands for display devices for displaying images are increasing, and various types of display devices such as liquid crystal display (LCD) devices and organic light emitting diode (OLED) display devices are utilized.

A display device includes a plurality of pixels and a plurality of switching elements for driving and controlling the plurality of pixels.

The description provided in the discussion of the related art section should not be assumed to be prior art merely because it is mentioned in or associated with that section. The discussion of the related art section can include information that describes one or more aspects of the subject technology, and the description in this section does not limit the present disclosure.

### BRIEF SUMMARY OF THE DISCLOSURE

Example embodiments of the present disclosure are directed to providing a display device in which it is possible to prevent or reduce a lateral leakage current between adjacent sub-pixels.

Example embodiments of the present disclosure are also directed to providing a display device in which a bank can include a black-based material to absorb external light incident on a lower portion of the bank.

Example embodiments of the present disclosure are also directed to providing a display device in which, since a first bank includes a second exposed portion exposed by a second bank and disposed between an overlapping portion and a first exposed portion and the second exposed portions are disposed to be spaced apart from each other (a protrusion structure or an angled structure is applied to the bank), it is possible to improve spreadability of a second encapsulation layer (or an organic encapsulation layer).

Example embodiments of the present disclosure are also directed to providing a display device in which an organic layer is formed integrally across all of sub-pixels, but, by forming a trench in a protective layer and guiding the organic layer to be separated from the trench, it is possible to prevent or reduce a lateral leakage current between adjacent sub-pixels.

Objects of the present disclosure are not limited to the above-described objects, and other technical objects can be inferred from the following embodiments.

According to one example embodiment of the present disclosure, there is provided a display device including a substrate including a display area including a plurality of sub-pixels, and a non-display area adjacent to the display area, an anode electrode disposed in each of the plurality of sub-pixels on the substrate, a bank disposed on the anode electrode, located at a boundary between adjacent sub-pixels, covering a periphery of an upper surface of the anode electrode, and including a first bank on the anode electrode and a second bank on the first bank, wherein the first bank includes an overlapping portion overlapping the second bank, a first exposed portion exposed by the second bank and including a side surface, and a second exposed portion exposed by the second bank and disposed between the overlapping and the first exposed portion, the second exposed portion is provided as a plurality of second exposed portions, and the plurality of adjacent second exposed portions are spaced apart from each other in a plan view.

According to one example embodiment of the present disclosure, there is provided a display device including a substrate including a display area including a plurality of sub-pixels, and a non-display area adjacent to the display area, an anode electrode disposed in each of the sub-pixels on the substrate in the display area, a bank disposed on the anode electrode in the display area, located at a boundary between adjacent sub-pixels, covering a periphery of an upper surface of the anode electrode, and including a first bank on the anode electrode and a second bank on the first bank, and an organic layer disposed on the anode electrode and the bank and disposed across the plurality of sub-pixels, wherein the first bank includes an overlapping portion overlapping the second bank, and an exposed portion exposed by the second bank, and an outline of the exposed portion has a plurality of bent portions in a plan view.

According to one example embodiment of the present disclosure, there is provided a display device including a substrate including a display area including a plurality of sub-pixels, and a non-display area adjacent to the display area; an anode electrode disposed in each of the plurality of sub-pixels on the substrate; a bank disposed on the anode electrode, located at a boundary between adjacent sub-pixels, covering a periphery of an upper surface of the anode electrode; an organic layer disposed on the anode electrode and the bank and disposed across the plurality of sub-pixels; and a protective layer disposed under the organic layer, and including a trench overlapping the bank and passing through the protective layer in a thickness direction.

Detailed matters of other embodiments are included in the detailed description and accompanying drawings.

It is to be understood that both the foregoing general description and the following detailed description of the present disclosure are examples and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plan view of a display device according to one or more example embodiments of the present disclosure.

FIG. 2 is a cross-sectional view illustrating a bent state of a display panel according to FIG. 1.

FIG. 3 is a cross-sectional view along line A-A′ in FIG. 1 according to embodiments of the present disclosure.

FIG. 4 is a specific cross-sectional view of a light-emitting part of FIG. 3 according to embodiments of the present disclosure.

FIG. 5 is a specific cross-sectional view of a light-emitting part according to a modified example of the present disclosure.

FIG. 6 is a cross-sectional view of a touch part according to FIG. 3 according to embodiments of the present disclosure.

FIG. 7 is a cross-sectional view along line B-B′ in FIG. 1 according to embodiments of the present disclosure.

FIG. 8 is a cross-sectional view along line C-C′ in FIG. 1 according to embodiments of the present disclosure.

FIG. 9 is a flat surface arrangement view of sub-pixels of a display area in FIG. 1 according to embodiments of the present disclosure.

FIG. 10 is a cross-sectional view along line D-D′ in FIG. 9 according to embodiments of the present disclosure.

FIG. 11 is a cross-sectional view along line E-E′ in FIG. 9 according to embodiments of the present disclosure.

FIG. 12 is a flat surface arrangement view of sub-pixels of a display area of a display device according to another example embodiment of the present disclosure.

FIG. 13 is a flat surface arrangement view of sub-pixels of a display area of a display device according to yet another example embodiment of the present disclosure.

FIG. 14 is a cross-sectional view of a display device according to yet another example embodiment of the present disclosure.

FIG. 15 is a cross-sectional view of the display device according to yet another example embodiment of the present disclosure.

FIG. 16 is a cross-sectional view of the display device according to yet another example embodiment of the present disclosure.

FIG. 17 is a cross-sectional view of the display device according to yet another example embodiment of the present disclosure.

FIG. 18 is a cross-sectional view of a display device according to yet another example embodiment of the present disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Reference will now be made in detail to embodiments of the present disclosure, examples of which can be illustrated in the accompanying drawings. The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations can be selected only for convenience of writing the specification and can be thus different from those used in actual products.

Hereinafter, embodiments will be described with reference to the accompanying drawings.

The same reference numerals indicate the same components. In addition, in the drawings, thicknesses, proportions, and dimensions of components can be exaggerated for effective description of technical contents. Scales of components shown in the drawings differ from the actual scale for convenience of description, and thus are not limited to the scales shown in the drawings.

In the specification, when a first component (or an area, a layer, a portion, or the like) is described as “on,” “connected,” or “coupled to” a second component, it means that the first component can be directly connected/coupled to the second component or a third component can be disposed therebetween.

The term “and/or” includes all one or more combinations that can be defined by the associated configurations. The term “at least one” includes all combinations related with any one item. For example, “at least one among a first element, a second element and a third element” can include all combinations of two or more elements selected from the first, second and third elements as well as each individual element of the first, second and third elements.

Terms such as first, second, A, B, (a), (b), and the like can be used to describe various components, but the components are not limited by the terms. The terms are used only for the purpose of distinguishing one component from another. For example, a first component can be referred to as a second component, and similarly, the second component can also be referred to as the first component without departing from the scopes of the example embodiments. The singular includes the plural unless the context clearly dictates otherwise. For example, an element described in the singular form is intended to include a plurality of elements, and vice versa, unless the context clearly indicates otherwise.

Terms such as “below,” “under,” “at a lower side,” “on,” “over,” “above,” and “at an upper side” or the like are used to describe the relationship between the components illustrated in the drawings. The terms are relative concepts and are described with respect to directions marked in the drawings. For example, as long as “immediately” or “directly” is not used, one or more other portions can be positioned between two portions. For example, where an element or layer is disposed “on” another element or layer, a third element or layer can be interposed therebetween. The spatially relative terms “below or beneath,” “lower,” “above,” “upper,” and the like can be used to easily describe the correlation with one element or components and another element or components as shown in the drawings. The spatially relative terms should be understood as the terms including different directions of elements in use or operation in addition to the directions shown in the drawings. For example, in case of turning the element shown in the drawing upside down, an element described as being disposed “below” or “beneath” another element can be disposed “above” another element. Accordingly, the example term “below” can include both downward and upward directions.

It should be understood that term such as “includes” “has” “contain,” “constitute,” “make up of,” or “formed of,” and the like is intended to specify the presence of features, numbers, steps, operations, components, parts, or a combination thereof described in the specification and does not preclude the presence or addition possibility of one or more other features, numbers, steps, operations, components, parts, or combinations thereof in advance. Further, the term “can” fully encompasses all the meanings and coverages of the term “may” and vice versa.

Features of various embodiments of the present disclosure can be coupled or combined partially or entirely, various technological interworking and driving are made possible, and the example embodiments can be implemented independently of each other or implemented together in an associated relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning, for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

The features of the various embodiments of the present disclosure can be partially or entirely combined with each other, and can be technically associated with each other or operate with each other. The embodiments can be implemented independently of each other and can be implemented together in an association relationship.

Hereinafter, a display device according to embodiments of the present disclosure will be described with reference to the accompanying drawings as follows. All the components of each display device according to all embodiments of the present disclosure are operatively coupled and configured.

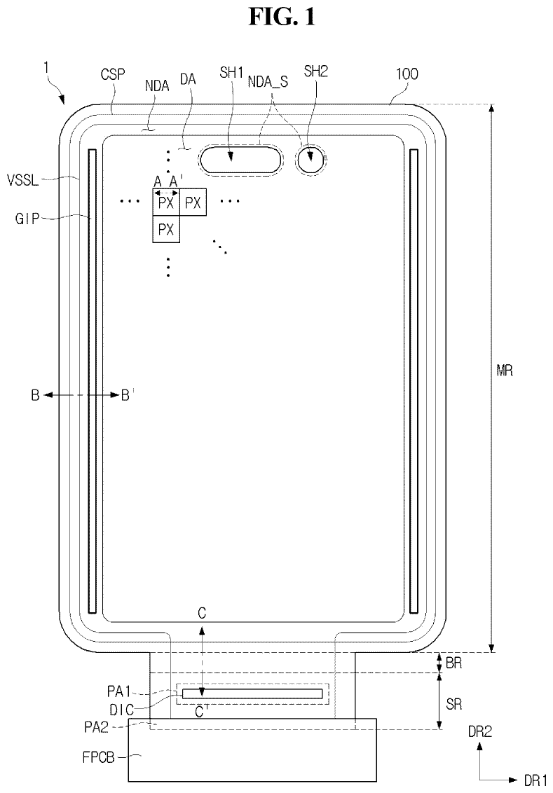

FIG. 1 is a plan view of a display device according to one example embodiment of the present disclosure.

Referring to FIG. 1, a display device 1 according to one example embodiment of the present disclosure can include a display panel 100. The display panel 100 can include a display area DA including a plurality of pixels PX in which an image is displayed, and a non-display area NDA adjacent to (for example, surrounding) the display area DA in which an image is not displayed. The flat surface shape of the display area DA can have a rectangular shape. However, the example embodiments of the present disclosure are not limited thereto, and the flat surface shape of the display area DA can be a square, circular, elliptical, or other polygonal shapes. For example, the display area DA can have a rectangular shape with rounded corners, but is not limited thereto and can also have a rectangular shape with angled corners. The non-display area NDA can also be referred to as an edge area or a bezel area.

In example embodiments, a first direction DR1 and a second direction DR2 are different directions and intersect each other, for example, directions that intersect vertically in a plan view. In FIG. 1, the first direction DR1 can be generally the same as an extension direction of short sides of the display panel 100, and the second direction DR2 can be the same as an extension direction of long sides of the display panel 100. However, the directions described in the example embodiments should be understood as indicating relative directions, and the embodiments are not limited to the described directions.

The display area DA can include short sides extending in the first direction DR1 and long sides extending in the second direction DR2. The non-display area NDA can refer to an area outside of the display area DA. The non-display area NDA can surround the display area DA. The non-display area NDA can be disposed at one side and the other side of the display area DA in the first direction DR1 and one side and the other side of the display area DA in the second direction DR2. Several types of signal lines can be disposed in the non-display area NDA, and several types of driving circuits can be connected thereto.

The display panel 100 can further include a sensor non-display area NDA_S and a sensor hole SH surrounded by the sensor non-display area NDA_S. The sensor hole SH1 and SH2 can be surrounded by the display area DA in a plan view. The sensor hole SH1 and SH2 can be, for example, two sensor holes as in FIG. 1, but the embodiments of the present disclosure are not limited thereto. For example, the sensor hole can be provided as one sensor hole. For example, the sensor hole can be provided as more than two sensor holes. The two sensor holes SH1 and SH2 can each include a sensor hole in which an infrared sensor is disposed and a sensor hole in which a camera sensor is disposed, but the embodiments of the present disclosure are not limited thereto. The sensor non-display area NDA_S can be disposed between the sensor holes SH1 and SH2 and the display area DA. The sensor non-display area NDA_S can completely surround the sensor holes SH1 and SH2, but the embodiments of the present disclosure are not limited thereto. A pixel PX may not be disposed in the sensor non-display area NDA_S.

A gate driving unit GIP can be disposed in the non-display area NDA located at one side and the other side of the display area DA in the first direction DR1. The gate driving unit GIP can be a circuit for driving a plurality of gate lines, and can supply gate signals to the plurality of gate lines. A low-potential voltage line VSSL can be disposed outside the gate driving unit GIP on the non-display area NDA. For example, as illustrated in FIG. 1, the low-potential voltage line VSSL can extend from a printed circuit board FPCB, pass a sub-region SR and a bending region BR, can be located outside the gate driving unit GIP on the non-display area NDA, and disposed to surround the display area DA.

The non-display area NDA located at the other side of the display area DA in the second direction DR2 can extend further from a central portion of the other side toward the other side of the display area DA in the second direction DR2. A width of the non-display area NDA in the first direction DR1 further extending from the central portion of the other side toward the other side of the display area DA in the second direction DR2 can be smaller than a width of the non-display area NDA in the first direction DR1 adjacent to the other side of the display area DA in the second direction DR2.

A display device 1 can include a main region MR, the sub-region SR, and the bending region BR between the main region MR and the sub-region SR. The display area DA and the non-display area NDA surrounding four surfaces of the display area DA can form the main region MR, and a portion extending from the central portion of the other side toward the other side of the display area DA in the second direction DR2 can form the bending region BR and the sub-region SR. The bending region BR can be disposed between the sub-region SR and the main region MR. The sub-region SR can include a first pad area PA1 and a second pad area PA2 located at an end portion of the other side of the sub-region SR in the second direction DR2. The display device 1 can further include a data driving unit DIC and a printed circuit board FPCB. The data driving unit DIC can be a unit for driving the plurality of data lines, and can supply data signals to the plurality of data lines. The data driving unit DIC can be disposed in the first pad area PA1, and the printed circuit board FPCB can be attached to the second pad area PA2. For example, the sub-region SR and the bending region BR can be disposed between the main region MR and the printed circuit board FPCB. A plurality of pads connected to the data driver 300 and the printed circuit board 500 can be disposed in each of the first pad area PA1 and the second pad area PA2. A plurality of pads connected to the data driving unit DIC and the printed circuit board FPCB can be disposed in each of the first pad area PA1 and the second pad area PA2. The data driving unit DIC can be configured, for example, in the form of a driving chip (IC), but is not limited thereto. In one example embodiment, a case in which the data driving unit DIC is disposed by a chip on plastic method in which the data driving unit DIC is directly mounted on the display panel 100 is described, but the embodiments of the present disclosure are not limited thereto, and the data driving unit DIC can be disposed by a chip on glass or chip on film method.

In one or more aspects, the data driving unit DIC can be connected to the display panel 100 by a tape-automated-bonding (TAB) technique, or connected to a conductive pad such as a bonding pad of the display panel 100 by a chip-on-glass (COG) technique or a chip-on-panel (COP) technique, or connected to the display panel 100 by a chip-on-film (COF) technique, without being limited thereto.

The display panel 100 according to one example embodiment of the present disclosure can further include a crack sensing pattern CSP surrounding the low-potential voltage line VSSL. The crack sensing pattern CSP can be disposed to completely surround the display area DA as illustrated in FIG. 1, without being limited thereto. For example, the crack sensing pattern CSP can be disposed outside the low-potential voltage line VSSL. However, the example embodiments of the present disclosure are not limited thereto, and the crack sensing pattern CSP can be disposed to partially surround the display area DA. For example, a part of the crack sensing pattern CSP may not be disposed in the non-display area NDA of the other side of the display area DA in the second direction DR2. For example, the crack sensing pattern CSP can be disposed to completely or partially surround the display area DA in the non-display area NDA.

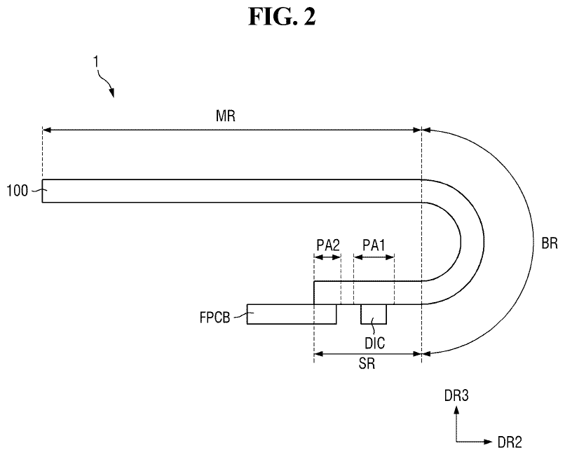

FIG. 2 is a cross-sectional view illustrating a bent state of a display panel according to FIG. 1.

Referring to FIG. 2, the bending region BR of the display panel 100 of the display device 1 according to one example embodiment of the present disclosure can be bent in a thickness direction (or a third direction DR3). Accordingly, the main region MR and the sub-region SR can overlap each other in the thickness direction. For example, the bending region BR can be disposed between the main region MR and the sub-region SR. The display panel 100 can be bent in such a manner that a lower surface of the main region MR faces an upper surface of the sub-region SR. The printed circuit board FPCB can be attached to an end portion of the sub-region SR. For example, the main region MR and the printed circuit board FPCB can overlap each other in the thickness direction, without being limited thereto.

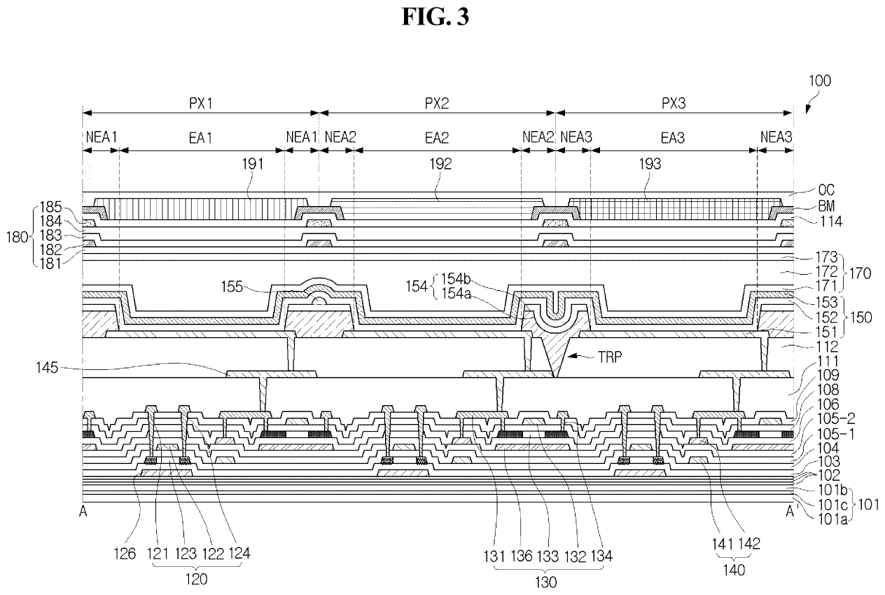

FIG. 3 is a cross-sectional view along line A-A′ in FIG. 1.

Referring to FIG. 3, the pixel PX (see FIG. 1) of the display panel 100 can include a plurality of sub-pixels. For example, the pixel PX (see FIG. 1) of the display panel 100 can include the sub-pixels PX1, PX2, and PX3, without being limited thereto. More or less sub-pixels can be included. For example, the sub-pixels PX1, PX2, and PX3 can comprise a first sub-pixel PX1, a second sub-pixel PX2 and a third sub-pixels PX3. The sub-pixels PX1, PX2, and PX3 can be one selected from a red sub-pixel, a green sub-pixel and a blue sub-pixel. The first sub-pixel PX1 can be a red sub-pixel, the second sub-pixel PX2 can be a green sub-pixel, and the third sub pixel PX3 can be a blue sub-pixel, but the embodiments of the present disclosure are not limited thereto. In some example embodiments, the pixel PX further includes a fourth sub-pixel, and the fourth sub-pixel can be a white sub-pixel, but the embodiments of the present disclosure are not limited thereto.

The display panel 100 can include a substrate 101, a first thin film transistor 120, a second thin film transistor 130, a light-emitting part 150, an encapsulation part 170, a touch part 180, a filter insulating layer 114, a black matrix BM, color filters 191, 192, and 193, and a planarization layer OC, without being limited thereto. The display panel 100 can include at least one panel insulating layer between the substrate 101 and the light-emitting part 150. The at least one panel insulating layer can include at least one of a buffer layer 102, a first insulating layer 103, a second insulating layer 104, a 3-1 insulating layer 105-1, a 3-2 insulating layer 105-2, a fourth insulating layer 106, a fifth insulating layer 108, a sixth insulating layer 109, a first protective layer 111, and a second protective layer 112, without being limited thereto. At least one touch insulating layer can be disposed above the light-emitting part 150. The at least one touch insulating layer can include at least one of a touch buffer layer 181, a first touch insulating layer 183, and a second touch insulating layer 184.

The substrate 101 can include one or more plastic materials, without being limited thereto. For example, the substrate 101 can be a multi-substrate including a plurality of plastic materials, such as polyimide, etc. For example, the substrate 101 can include a first substrate portion 101a and a second substrate portion 101b each including a plastic material, and a third substrate portion 101c including an inorganic insulation material between the first substrate portion 101a and the second substrate portion 101b, but the embodiments of the present disclosure are not limited thereto.

For example, the substrate 101 can include glass or a flexible polymer film. For example, the flexible polymer film can be made of any one of polyethylene terephthalate (PET), polycarbonate (PC), acrylonitrile-butadiene-styrene copolymer (ABS), polymethyl methacrylate (PMMA), polyethylene polyether sulfone (PES), cyclic olefin copolymer (COC), triacetylcellulose (TAC) film, polyvinyl alcohol (PVA) film, polyimide (PI) film, and polystyrene (PS), which is only an example and is not necessarily limited thereto.

The buffer layer 102 can be disposed on the substrate 101. The buffer layer 102 can minimize or delay the diffusion of moisture or oxygen penetrating the substrate 101. The buffer layer 102 can be formed of an inorganic insulation material, such as silicon nitride (SiNₓ) or silicon oxide (SiOₓ), but the embodiments of the present disclosure are not limited thereto. For example, the buffer layer 102 can be formed by alternately stacking silicon nitride (SiNₓ) and silicon oxide (SiOₓ) at least once, but the embodiments of the present disclosure are not limited thereto. For example, the buffer layer 102 can be formed by inorganic film in a single layer, and the inorganic film in a single layer can be a silicon oxide (SiO) film or a silicon nitride (SiN) film, but the embodiments of the present disclosure are not limited thereto.

A first light-shielding layer 126 can be disposed on the buffer layer 102. The first light-shielding layer 126 can prevent or reduce light from transmitting a first semiconductor layer 123 of the first thin film transistor 120, thereby extending the life of the first thin film transistor 120. For example, the first semiconductor layer 123 can be disposed to overlap the first light-shielding layer 126. The first light-shielding layer 126 can be formed of a single layer or multiple layers formed of one of molybdenum (Mo), aluminum (Al), chromium (Cr), nickel (Ni), neodymium (Nd), and copper (Cu) or an alloy thereof, but the embodiments of the present disclosure are not limited thereto.

The first insulating layer 103 can be disposed on the buffer layer 102 and the first light-shielding layer 126. For example, the first insulating layer 103 can be disposed on a portion of the buffer layer 102 and the first light-shielding layer 126. The first insulating layer 103 can be disposed between the first thin film transistor 120 and the first light-shielding layer 126. The first insulating layer 103 can prevent or reduce a short circuit between a component of the first thin film transistor 120 and the first light-shielding layer 126. The first insulating layer 103 can be formed of the same or substantially same material as the buffer layer 102, but the embodiments of the present disclosure are not limited thereto. For example, the first insulating layer 103 can be formed of an inorganic insulation material, such as silicon nitride (SiNₓ) or silicon oxide (SiOₓ), but the embodiments of the present disclosure are not limited thereto. For example, the first insulating layer 103 can be formed by alternately stacking silicon nitride (SiNₓ) and silicon oxide (SiOₓ) at least once, but the embodiments of the present disclosure are not limited thereto.

The first thin film transistor 120 can be disposed on the first insulating layer 103. The first thin film transistor 120 can include a first source electrode 121, a first gate electrode 122, the first semiconductor layer 123, and a first drain electrode 124.

The first semiconductor layer 123 can be disposed on the first insulating layer 103. The first semiconductor layer 123 can include a metal oxide semiconductor, such as indium-gallium-zinc oxide (IGZO), and a silicon-based semiconductor material, such as amorphous silicon, polycrystalline silicon, etc., but the embodiments of the present disclosure are not limited thereto. The first semiconductor layer 123 can include a source area, a drain area and a channel area between the source area and the drain area.

Since the polycrystalline semiconductor layer has higher mobility than the amorphous semiconductor layer and the oxide semiconductor layer, power consumption can be less, and reliability can be excellent. Accordingly, a driving transistor can be formed of the polycrystalline semiconductor layer.

A second insulating layer 104 can be disposed on the first semiconductor layer 123. The second insulating layer 104 can be formed of the same or substantially same material as the first insulating layer 103, but the embodiments of the present disclosure are not limited thereto. The second insulating layer 104 can be formed of the same or substantially same material as the buffer layer 102, but the embodiments of the present disclosure are not limited thereto. The second insulating layer 104 can prevent or reduce a short circuit between the first semiconductor layer 123 and another component of the first thin film transistor 120.

The first gate electrode 122 can be disposed on the second insulating layer 104. The first gate electrode 122 can be disposed on the second insulating layer 104 to overlap the channel area of the first semiconductor layer 123. The first gate electrode 122 can be formed of a conductive material such as a metallic material. For example, the first gate electrode 122 can be formed of a single layer or multiple layers formed of molybdenum (Mo), copper (Cu), titanium (Ti), aluminum (Al), chromium (Cr), gold (Au), nickel (Ni), neodymium (Nd), or compounds thereof, but the embodiments of the present disclosure are not limited thereto.

The first gate electrode 122 can be disposed along with a gate line. For example, the gate line can be formed of the same or substantially same material as the first gate electrode 122 and formed on the same layer as the first gate electrode 122, but the embodiments of the present disclosure are not limited thereto.

The third insulating layers 105-1 and 105-2 can be disposed on the first gate electrode 122. The third insulating layers 105-1 and 105-2 can be formed by alternately stacking silicon nitride (SiNₓ) and silicon oxide (SiOₓ) at least once, but the embodiments of the present disclosure are not limited thereto. For example, the 3-1 insulating layer 105-1 can include silicon oxide (SiOₓ), and the 3-2 insulating layer 105-2 can include silicon nitride (SiNₓ), but the embodiments of the present disclosure are not limited thereto.

The first source electrode 121 and the first drain electrode 124 can be disposed on the third insulating layers 105-1 and 105-2.

The first source electrode 121 and the first drain electrode 124 can be electrically connected to the first semiconductor layer 123 through contact holes. The first source electrode 121 and the first drain electrode 124 can be formed of a conductive material such as a metallic material. For example, the first source electrode 121 and the first drain electrode 124 can be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The first source electrode 121 and the first drain electrode 124 can be disposed along with a data line. For example, the data line can be formed of the same or substantially same material as the first source electrode 121 and the first drain electrode 124 and formed on the same layer as the first source electrode 121 and the first drain electrode 124, but the embodiments of the present disclosure are not limited thereto.

A storage electrode 140 can be disposed to be spaced apart from the first thin film transistor 120. The storage electrode 140 can include a first storage electrode 141 and a second storage electrode 142, but the embodiments of the present disclosure are not limited thereto.

The first storage electrode 141 can be formed of the same or substantially same material as the first gate electrode 122 and disposed on the same layer as the first gate electrode 122, but the embodiments of the present disclosure are not limited thereto.

The second storage electrode 142 can be disposed on the first storage electrode 141. The second storage electrode 142 can be disposed on the third insulating layers 105-1 and 105-2, and the third insulating layers 105-1 and 105-2 between the first storage electrode 141 and the second storage electrode 142 can be used as a dielectric to generate a capacitance. The second storage electrode 142 can be formed of the same or substantially same material as the first storage electrode 141, but the embodiments of the present disclosure are not limited thereto. For example, the second storage electrode 142 can be disposed to overlap the first storage electrode 141, but the embodiments of the present disclosure are not limited thereto.

The second thin film transistor 130 can be disposed to be spaced apart from the first thin film transistor 120 and the storage electrode 140. The second thin film transistor 130 can include a second source electrode 131, a second gate electrode 132, a second semiconductor layer 133, and a second drain electrode 134.

A second light-shielding layer 136 can be disposed on the same layer as the second storage electrode 142.

Similar to the first light-shielding layer 126, the second light-shielding layer 136 can prevent or reduce light from traveling to the second semiconductor layer 133 of the second thin film transistor 130, thereby extending the life of the second thin film transistor 130. For example, the second semiconductor layer 133 can be disposed to overlap the second light-shielding layer 136. The second light-shielding layer 136 can be formed of a single layer or multiple layers formed of one of molybdenum (Mo), aluminum (Al), chromium (Cr), nickel (Ni), neodymium (Nd), and copper (Cu) or an alloy thereof, but the embodiments of the present disclosure are not limited thereto.

The fourth insulating layer 106 can be disposed on the second light-shielding layer 136. The fourth insulating layer 106 can be formed of the same or substantially same material as the first insulating layer 103, the second insulating layer 104, or the third insulating layers 105-1 and 105-2, but the embodiments of the present disclosure are not limited thereto. For example, the fourth insulating layer 106 can be formed of an inorganic insulation material, such as silicon nitride (SiNₓ) or silicon oxide (SiOₓ), but the embodiments of the present disclosure are not limited thereto.

The second semiconductor layer 133 can be disposed on the fourth insulating layer 106. The second semiconductor layer 133 can include a source area, a drain area, and a channel area between the source area and the drain area.

The second semiconductor layer 133 can include a metal oxide semiconductor, such as indium-gallium-zinc oxide (IGZO), and a silicon-based semiconductor material, such as amorphous silicon, polycrystalline silicon, etc., but the embodiments of the present disclosure are not limited thereto.

The fifth insulating layer 108 can be disposed on the second semiconductor layer 133. The fifth insulating layer 108 can be formed of the same or substantially same material as the first insulating layer 103, the second insulating layer 104, the third insulating layers 105-1 and 105-2, or the fourth insulating layer 106, but the embodiments of the present disclosure are not limited thereto.

The second gate electrode 132 can be disposed on the fifth insulating layer 108. The second gate electrode 132 can be disposed on the fifth insulating layer 108 to overlap the channel area of the second semiconductor layer 133.

The second gate electrode 132 can be formed of the same or substantially same material as the first gate electrode 122, but the embodiments of the present disclosure are not limited thereto. The second gate electrode 132 can be formed of a conductive material such as a metallic material. For example, the second gate electrode 132 can be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the present disclosure are not limited thereto.

The sixth insulating layer 109 can be disposed on the second gate electrode 132. The sixth insulating layer 109 can be formed of the same or substantially same material as the first insulating layer 103, the second insulating layer 104, the third insulating layers 105-1 and 105-2, the fourth insulating layer 106, or the fifth insulating layer 108, but the embodiments of the present disclosure are not limited thereto.

The first source electrode 121, the first drain electrode 124, the second source electrode 131, and the second drain electrode 134 can be disposed on the sixth insulating layer 109.

The second source electrode 131 and the second drain electrode 134 can be formed of the same or substantially same material as the first source electrode 121 and the first drain electrode 124 and disposed on the same layer as the first source electrode 121 and the first drain electrode 124, but the embodiments of the present disclosure are not limited thereto. For example, the second source electrode 131 and the second drain electrode 134 can be formed of a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto. For example, the second source electrode 131 can be electrically connected to the second storage electrode 142. The second source electrode 131 can pass through the sixth insulating layer 109, the fifth insulating layer 108, and the fourth insulating layer 106 and can be electrically connected to the second storage electrode 142. For example, the second source electrode 131 can be electrically connected to the second storage electrode 142 through contact holes formed in the sixth insulating layer 109, the fifth insulating layer 108, and the fourth insulating layer 106.

The first thin film transistor 120 and second thin film transistor 130 can be any one of a driving transistor and a switching transistor. For example, the first thin film transistor 120 can be a driving transistor, and the second thin film transistor 130 can be a switching transistor, but the embodiments of the present disclosure are not limited thereto.

At least one protective layer can be disposed on the first source electrode 121 and the first drain electrode 124. For example, the plurality of protective layers can comprise a first protective layer 111 and a second protective layer 112, but the embodiments of the present disclosure are not limited thereto. More or less protective layers can be included.

A first protective layer 111 can be disposed on the first source electrode 121 and the first drain electrode 124.

The first protective layer 111 can planarize an upper portion of the first thin film transistor 120 and protect the first thin film transistor 120. For example, the first protective layer 111 can planarize a step caused by the first thin film transistor 120. The first protective layer 111 can be formed of an organic material. For example, the first protective layer 111 can be formed of an organic material containing an acrylic resin, an epoxy resin, a phenolic resin, a polyamide resin, or a polyimide resin, but the embodiments of the present disclosure are not limited thereto.

The second protective layer 112 can be disposed on the first protective layer 111. The second protective layer 112 can be formed of the same or substantially same material as the first protective layer 111, but the embodiments of the present disclosure are not limited thereto.

In some example embodiments, a third protective layer can be further disposed on an upper surface of the second protective layer 112, but the embodiments of the present disclosure are not limited thereto.

A connection electrode 145 can be disposed between the first protective layer 111 and the second protective layer 112.

The connection electrode 145 can electrically connect the first thin film transistor 120 to the light-emitting part 150. The connection electrode 145 can be formed of the same or substantially same material as the first source electrode 121 and the first drain electrode 124, but the embodiments of the present disclosure are not limited thereto.

The connection electrode 145 can be formed of a single layer or multiple layers made of one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The light-emitting part 150 can be disposed on the second protective layer 112. The light-emitting part 150 can include an anode electrode 151, an organic layer 152, and a cathode electrode 153.

The anode electrode 151 can be disposed on the second protective layer 112. The anode electrode 151 can be electrically connected to the first thin film transistor 120 through a contact hole formed in the second protective layer 112. The anode electrode 151 can be a reflective electrode that reflects light, but the embodiments of the present disclosure are not limited thereto. The anode electrode 151 can include a metallic material with high reflectivity, such as a stacking structure (Ti/Al/Ti) of aluminum (Al) and titanium (Ti), a stacking structure (ITO/Al/ITO) of aluminum (Al) and indium tin oxide (ITO), or an APC alloy and can be formed of a single layer or multiple layers, but the embodiments of the present disclosure are not limited thereto.

The organic layer 152 can be disposed on the anode electrode 151. The organic layer 152 can include one or more light-emitting structures (or light-emitting elements or elements) stacked on the anode electrode 151 in the order or reverse order of a hole transfer layer and an electron transfer layer. For example, the hole transfer layer can include a hole transporting layer, a hole injecting layer, an electron blocking layer, a p-type charge generation layer, etc., but the embodiments of the present disclosure are not limited thereto. For example, the electron transfer layer can include an electron transporting layer, an electron injecting layer, a hole blocking layer, an n-type charge generation layer, etc., but the embodiments of the present disclosure are not limited thereto. The organic layer 152 can be an organic light-emitting layer, an inorganic light-emitting layer, a quantum dot light-emitting layer, a micro light-emitting diode, a micro mini light-emitting diode, etc., but the embodiments of the present disclosure area are not limited thereto. For example, the organic layer 152 of the display panel 100 according to one example embodiment of the present disclosure can include an organic light-emitting layer. The organic layer 152 can include a red light-emitting layer, a green light-emitting layer, and a blue light-emitting layer. The organic layer 152 can be a white light-emitting layer, but the embodiments of the present disclosure are not limited thereto. Hereinafter, a specific structure of the organic layer 152 according to one example embodiment will be described.

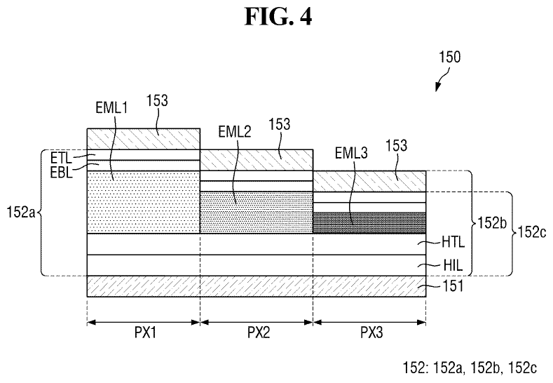

FIG. 4 is a specific cross-sectional view of a light-emitting part of FIG. 3.

Referring to FIG. 4, the light-emitting part 150 can include a plurality of sub-pixels, such as the first sub-pixel PX1, the second sub-pixel PX2, and the third sub-pixel PX3, but the embodiments of the present disclosure are not limited thereto.

A thickness of the light-emitting part 150 in each sub-pixel PX1, PX2, or PX3 can be different, but the embodiments of the present disclosure are not limited thereto, and the thickness of the light-emitting part 150 in each sub-pixel PX1, PX2, or PX3 can be the same.

The organic layer 152 can include a plurality of organic layers disposed in the plurality of sub-pixels, respectively. For example, the organic layer 152 can include a first organic layer 152a disposed in the first sub-pixel PX1, a second organic layer 152b disposed in the second sub-pixel PX2, and a third organic layer 152c disposed in the third sub-pixel PX3, but the embodiments of the present disclosure are not limited thereto. The light-emitting layers EML1, EML2, and EML3 of the organic layers 152a, 152b, and 152c can be physically separated, but lower layers and upper layers of the light-emitting layers EML1, EML2, and EML3 can be formed integrally across the sub-pixels PX1, PX2, and PX3. A thicknesses of each light-emitting layer EML1, EML2, or EML3 can be different. For example, a thickness of a first light-emitting layer EML1 can be the greatest, a thickness of a second light-emitting layer EML2 can be the second greatest, and a thickness of the third light-emitting layer EML3 can be the smallest, but the embodiments of the present disclosure are not limited thereto.

The hole injecting layer HIL can be disposed on the anode electrode 151. The hole injecting layer HIL can be located between the anode electrode 151 and the light-emitting layers EML1, EML2, and EML3. The hole injecting layer HIL can be formed integrally across the sub-pixels PX1, PX2, and PX3. For example, the hole injecting layer HIL can be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl)phenyl)-9H-fluoren-2-amine, etc., but the embodiments of the present disclosure are not limited thereto.

A hole transporting layer HTL can be disposed on the hole injecting layer HIL. The hole transporting layer HTL can be located between the hole injecting layer HIL and the light-emitting layers EML1, EML2, and EML3. The hole transporting layer HTL can be formed integrally across the sub-pixels PX1, PX2, and PX3. The hole transporting layer HTL can be formed of one or more selected from the group consisting of arylamine-based materials, such as NPB (N,N-naphthyl-N,N′-phenyl benzidine), TPD (N,N′-bis-(3-methylphenyl)-N,N′-bis-(phenyl)-benzidine), PPD, TTBND, FFD, p-dmDPS, and TAPC, starbust aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N,N-dinaphthylN,N′-diphenyl benzidine), S-TAD, and MTDATA (4,4′,4″-Tris (N-3-methylphenyl-N-phenyl-amino)triphenylamine), but the embodiments of the present disclosure are not limited thereto.

The light-emitting layers EML1, EML2, and EML3 can be disposed on the hole transporting layer HTL. The light-emitting layers EML1, EML2, and EML3 can comprise the first light-emitting layer EML1, the second light-emitting layer EML2 and the third light-emitting layer EML3. The first light-emitting layer EML I can be disposed in the first sub-pixel PX1, the second light-emitting layer EML2 can be disposed in the second sub-pixel PX2, and the third light-emitting layer EML3 can be disposed in the third sub-pixel PX3.

A thicknesses of each light-emitting layer EML1, EML2, or EML3 can be different. For example, the first light-emitting layer EML I can be formed in a thickness of 600 to 800 Å, the second light-emitting layer EML2 can be formed in a thickness of 300 to 500 Å, and the third light-emitting layer EML3 can be formed in a thickness of 100 to 300 Å, but the embodiments of the present disclosure are not limited thereto.

Each of the first light-emitting layer EML1, the second light-emitting layer EML2, and the third light-emitting layer EML3 can include a material that can emit light in the visible light range by receiving and combining holes and electrons.

An electron blocking layer EBL can be disposed on each light-emitting layer EML1, EML2, or EML3. The electron blocking layer EBL can be disposed integrally across the sub-pixels PX1, PX2, and PX3.

An electron transporting layer ETL can be disposed on the electron blocking layer EBL. The electron transporting layer ETL can be disposed integrally across the sub-pixels PX1, PX2, and PX3. The electron transporting layer ETL can be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl) phenyl]-1-phenyl-1H-benzimidazole), but the embodiments of the present disclosure are not limited thereto.

The cathode electrode 153 can be disposed on the electron transporting layer ETL.

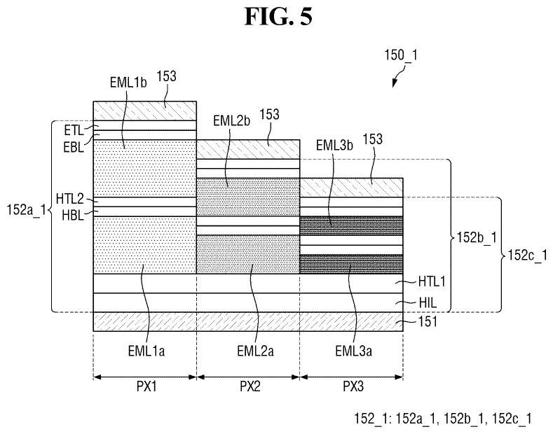

FIG. 5 is a specific cross-sectional view of a light-emitting part according to a modified example.

Referring to FIG. 5, an organic layer 152_1 can include a plurality organic layers disposed in the plurality of sub-pixels. For example, the organic layer 152_1 can include organic layers 152a_1, 152b_1 and 152c_1, but the embodiments of the present disclosure are not limited thereto. Referring to FIGS. 4 and 5, an organic layer 152_1 can include a first organic layer 152a_1 disposed in the first sub-pixel PX1, a second organic layer 152b_1 disposed in the second sub-pixel PX2, and a third organic layer 152c_1 disposed in the third sub-pixel PX3.

The light-emitting layers of each organic layer 152a_1, 152b_1, or 152c_1 can be physically separated, but the lower layers and upper layers of the light-emitting layers can be formed integrally across the sub-pixels PX1, PX2, and PX3. The thickness of each light-emitting layer can be different, but the embodiments of the present disclosure are not limited thereto. For example, the thickness of the first light-emitting layer of the first sub-pixel can be the greatest, the thickness of the second light-emitting layer of the second sub-pixel can be the second greatest, and the thickness of the third light-emitting layer of the third sub-pixel can be the smallest, but the embodiments of the present disclosure are not limited thereto. For example, the thickness of the first light-emitting layer EML1a of the first sub-pixel PX1 can be the greatest, the thickness of the second light-emitting layer EML2a of the second sub-pixel PX2 can be the second greatest, and the thickness of the third light-emitting layer EML3a of the third sub-pixel PX3 can be the smallest, but the embodiments of the present disclosure are not limited thereto. In addition, the light-emitting layers of each organic layer 152a_1, 152b_1, or 152c_1 can be provided as two or more light-emitting layers.

The hole injecting layer HIL can be disposed on the anode electrode 151. The hole injecting layer HIL can be located between the anode electrode 151 and the light-emitting layers EML1a, EML2a, and EML3a disposed in the sub-pixels PX1, PX2 and PX3. The hole injecting layer HIL can be formed integrally across the sub-pixels PX1, PX2, and PX3. For example, the hole injecting layer HIL can be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl) phenyl)-9H-fluoren-2-amine, etc., but the embodiments of the present disclosure are not limited thereto.

A first hole transporting layer HTL1 can be disposed on the hole injecting layer HIL. The first hole transporting layer HTL1 can be located between the hole injecting layer HIL and light-emitting layers EML1a, EML2a, and EML3a of the sub-pixels PX1, PX2, and PX3. The first hole transporting layer HTL1 can be formed integrally across the sub-pixels PX1, PX2, and PX3. The first hole transporting layer HTL I can be formed of one or more selected from the group consisting of arylamine-based materials, such as NPB (N,N-naphthyl-N,N′-phenyl benzidine), TPD (N,N′-bis-(3-methylphenyl)-N,N′-bis-(phenyl)-benzidine), PPD, TTBND, FFD, p-dmDPS, and TAPC, starbust aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N,N-dinaphthyIN,N′-diphenyl benzidine), s-TAD, and MTDATA (4,4′,4″-Tris (N-3-methylphenyl-N-phenyl-amino)-triphenylamine), but the embodiments of the present disclosure are not limited thereto.

The light-emitting layers EML1a, EML2a, and EML3a can be disposed on the first hole transporting layer HTL1. A 1-1 light-emitting layer EML1a can be disposed in the first sub-pixel PX1, a 2-1 light-emitting layer EML2a can be disposed in the second sub-pixel PX2, and a 3-1 light-emitting layer EML3a can be disposed in the third sub-pixel PX3. Each of the light-emitting layers EML1a, EML2a, and EML3a can be the same as each of the light-emitting layers EML1, EML2, and EML3 of FIG. 4.

A thicknesses of each light-emitting layer EML1a, EML2a, or EML3a can be different. For example, the thickness of the 1-1 light-emitting layer EML1a can be the greatest, the thickness of the 2-1 light-emitting layer EML2a can be the second greatest, and the thickness of the 3-1 light-emitting layer EML3a can be the smallest, but the embodiments of the present disclosure are not limited thereto. For example, the 1-1 light-emitting layer EML1a can be formed in a thickness of 600 to 800 Å, the 2-1 light-emitting layer EML2a can be formed in a thickness of 300 to 500 Å, and the 3-1 light-emitting layer EML3a can be formed in a thickness of 100 to 300 Å, but the embodiments of the present disclosure are not limited thereto.

A hole blocking layer HBL can be disposed on each light-emitting layer EML1a, EML2a, or EML3a. The hole blocking layer HBL can be disposed integrally across the sub-pixels PX1, PX2, and PX3.

A second hole transporting layer HTL2 can be disposed on the hole blocking layer HBL. The second hole transporting layer HTL2 can be disposed between the hole blocking layer HBL and the light-emitting layers EML1b, EML2b, and EML3b. The second hole transporting layer HTL2 can be formed integrally across the sub-pixels PX1, PX2, and PX3. A material of the second hole transporting layer HTL2 can be the same as a material of the first hole transporting layer HTL1, but the embodiments of the present disclosure are not limited thereto.

The light-emitting layers EML1b, EML2b, and EML3b can be disposed on the second hole transporting layer HTL2. The light-emitting layers EML1b, EML2b, and EML3b can comprise a 1-2 light-emitting layer EML1b, a 2-2 light-emitting layer EML2b and a 3-2 light-emitting layer EML3b. A 1-2 light-emitting layer EML1b can be disposed in the first sub-pixel PX1, a 2-2 light-emitting layer EML2b can be disposed in the second sub-pixel PX2, and a 3-2 light-emitting layer EML3b can be disposed in the third sub-pixel PX3. Each of the light-emitting layers EML 1b, EML2b, and EML3b can be the same as each of the light-emitting layers EML1a, EML2a, and EML3a.

A thicknesses of each light-emitting layer EML 1b, EML2b, or EML3b can be different. For example, the thickness of the 1-2 light-emitting layer EML1b can be the greatest, the thickness of the 2-2 light-emitting layer EML2b can be the second greatest, and the thickness of the 3-2 light-emitting layer EML3b can be the smallest, but the embodiments of the present disclosure are not limited thereto. For example, the 1-2 light-emitting layer EML1b can be formed in a thickness of 600 to 800 Å, the 2-2 light-emitting layer EML2b can be formed in a thickness of 300 to 500 Å, and the 3-2 light-emitting layer EML3b can be formed in a thickness of 100 to 300 Å, but the embodiments of the present disclosure are not limited thereto.

An electron blocking layer EBL can be disposed on each light-emitting layer EML1b, EML2b, or EML3b. The electron blocking layer EBL can be disposed integrally across the sub-pixels PX1, PX2, and PX3.

An electron transporting layer ETL can be disposed on the electron blocking layer EBL. The electron transporting layer ETL can be disposed integrally across the sub-pixels PX1, PX2, and PX3. The electron transporting layer ETL can be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl- 2-anthracenyl) phenyl]-1-phenyl-1H-benzimidazole), but the embodiments of the present disclosure are not limited thereto.

The cathode electrode 153 can be disposed on the electron transporting layer ETL. The cathode electrode 153 can be a transparent electrode that transmits light, but the embodiments of the present disclosure are not limited thereto. For example, the cathode electrode 153 can include a transparent conductive material, such as indium tin oxide (ITO) or indium zinc oxide (IZO), or a metal that transmits visible light, but the embodiments of the present disclosure are not limited thereto.

A bank 154 can be disposed to expose the anode electrode 151. The bank 154 can define openings (or the light-emitting areas EA1, EA2, and EA3) of the sub-pixels PX1, PX2, and PX3 and can be disposed to cover an edge portion (or a periphery) of the anode electrode 151. For example, the first sub-pixel PX1 can include a first light-emitting area EA1 and a first non-light-emitting area NEA1 around the first light-emitting area EA1, the second sub-pixel PX2 can include a second light-emitting area EA2 and a second non-light-emitting area NEA2 around the second light-emitting area EA2, and the third sub-pixel PX3 can include a third light-emitting area EA3 and a third non-light-emitting area NEA3 around the third light-emitting area EA3. For example, each non-light-emitting area NEA1, NEA2, or NEA3 can correspond to a boundary between adjacent sub-pixels PX1, PX2, and PX3.

The bank 154 can include two or more layers. For example, the bank 154 can include a first bank 154a, and a second bank 154b between the first bank 154a and the organic layer 152. The first bank 154a can include a black-based material. For example, the first bank 154a can be formed of a material containing black pigment, or an organic material, such as a benzocyclobutene resin, a polyimide resin, an acrylic resin, a photosensitive polymer, etc., but the embodiments of the present disclosure are not limited thereto. When the first bank 154a is formed of a material containing black pigment or black dye, the first bank 154a can be a black bank. For example, the first bank 154a can be made of an insulating material containing a black material. When the first bank 154a is formed of a material containing black pigment or black dye, it is possible to shield external light or light reflected from the outside, thereby further increasing the luminance of the display device. The first bank 154a can serve to absorb light re-reflected from a lower portion of the first bank 154a among the light incident from the outside. The second bank 154b can include a transparent-based material. The second bank 154b can be a transparent bank, but the embodiments of the present disclosure are not limited thereto. For example, the second bank 154b can be made of a transparent insulating material.

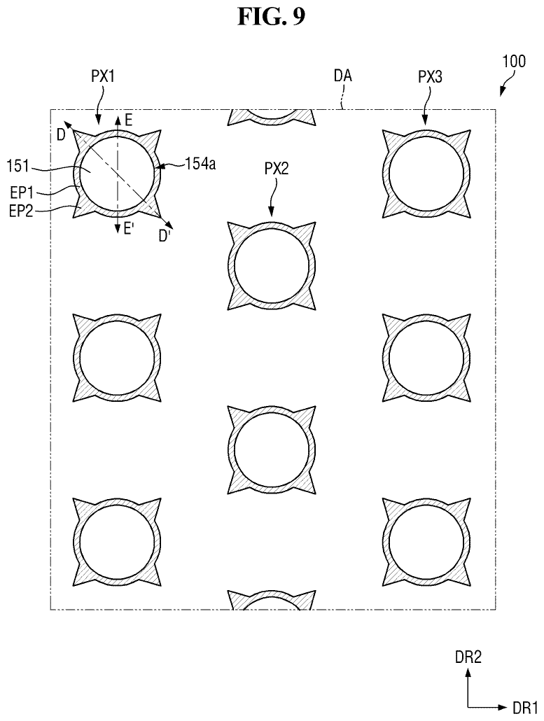

FIG. 3 illustrates side surfaces of the first bank 154a, which are aligned with side surfaces of the second bank 154b, but the side surfaces of the second bank 154b can be located close to boundaries between the non-light-emitting areas NEA1, NEA2, and NEA3 compared to the side surfaces of the first bank 154a. For example, the second bank 154b can expose an upper surface of the first bank 154a. The detailed descriptions thereof will be given below in FIGS. 9 to 11.

A spacer 155 can be further disposed on the bank 154. The spacer 155 can be formed of the same or substantially same material as the second bank 154b, but the embodiments of the present disclosure are not limited thereto. For example, the spacer 155 can be a transparent bank. For example, the spacer 155 can be disposed on at least one of the boundaries of the first to third sub-pixels PX1, PX2, and PX3, but the embodiments of the present disclosure are not limited thereto. In some example embodiments, the second bank 154b and the spacer 155 can be formed of the same or substantially same material and formed simultaneously through a halftone mask, but the embodiments of the present disclosure are not limited thereto.

The organic layer 152 can be disposed on the anode electrode 151, the bank 154, and the spacer 155. The cathode electrode 153 can be disposed on the organic layer 152.

The encapsulation part 170 can be disposed on the cathode electrode 153. The encapsulation part 170 can include one or more insulating layers. For example, the encapsulation part 170 can include a first encapsulation layer 171, a second encapsulation layer 172 disposed on the first encapsulation layer 171, and a third encapsulation layer 173 disposed on the second encapsulation layer 172, but the embodiments of the present disclosure are not limited thereto. More or less encapsulation layers can be included. The encapsulation part 170 can include one or more inorganic insulation material layers and one or more organic material layers. For example, the first encapsulation layer 171 and the third encapsulation layer 173 can include an inorganic insulation material, and the second encapsulation layer 172 can include an organic material, but the embodiments of the present disclosure are not limited thereto.

For example, the first encapsulation layer 171 and the third encapsulation layer 173 can include an inorganic insulation material capable of low-temperature deposition, such as silicon nitride (SiN), silicon oxide (SiO), silicon oxynitride (SiON) and aluminum oxide (Al₂O₃). For example, the second encapsulation layer 172 can include an organic material, such as acrylic resin, epoxy resin, polyimide, polyethylene and silicon oxycarbide (SiOC).

The touch part 180 can be disposed on the encapsulation part 170. The touch part 180 can include a plurality of layers. For example, the touch part 180 can include the touch buffer layer 181, a first touch conductive layer, the first touch insulating layer 183, the second touch insulating layer 184, and a second touch conductive layer, but the embodiments of the present disclosure are not limited thereto. In some example embodiments, a touch organic layer can be further disposed on the second touch conductive layer, but the embodiments of the present disclosure are not limited thereto.

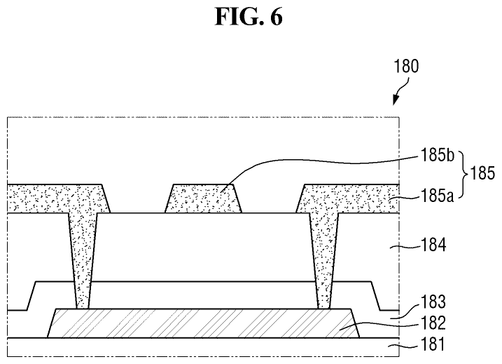

FIG. 6 is a cross-sectional view of a touch part according to FIG. 3.

Referring to FIGS. 3 and 6, the touch buffer layer 181 can be disposed on the encapsulation part 170. For example, the touch buffer layer 181 can be disposed on the third encapsulation layer 173. The touch buffer layer 181 can be formed of the same or substantially same material as the buffer layer 102, but the embodiments of the present disclosure are not limited thereto.

The first touch conductive layer can be disposed on the touch buffer layer 181. The first touch conductive layer can include a bridge electrode 182. The bridge electrode 182 and a sensor electrode 185 to be described below can be disposed at each of the boundaries between adjacent sub-pixels PX1, PX2, and PX3. For example, the bridge electrode 182 and the sensor electrode 185 can be disposed in the non-light-emitting areas NEA1, NEA2, and NEA3. The bridge electrode 182 and the sensor electrode 185 can overlap the black matrix BM to be described below in the thickness direction. The black matrix BM can be configured to cover the bridge electrode 182 and the sensor electrode 185. For example, the length of the black matrix BM can be greater than that of the bridge electrode 182 and the sensor electrode 185. Accordingly, the bridge electrode 182 and the sensor electrode 185 can be prevented or reduced from being visible from the outside. For example, a width of the black matrix BM can be smaller than a width of the bank 154.

The first touch insulating layer 183 and the second touch insulating layer 184 disposed on the first touch insulating layer 183 can be disposed on the first touch conductive layer. For example, the first touch insulating layer 183 and the second touch insulating layer 184 disposed on the first touch insulating layer 183 can be disposed on the bridge electrode 182. The first touch insulating layer 183 and the second touch insulating layer 184 disposed on the first touch insulating layer 183 can prevent a short circuit between the first touch conductive layer and the second touch conductive layer. The first touch insulating layer 183 can be formed of silicon oxide (SiOₓ), silicon nitride (SiNₓ), or multiple layers thereof, but the embodiments of the present disclosure are not limited thereto. The second touch insulating layer 184 can include an organic insulation material, but the embodiments of the present disclosure are not limited thereto, and the second touch insulating layer 184 can include the same or substantially same material as the first touch insulating layer 183, but the embodiments of the present disclosure are not limited thereto.

The second touch conductive layer can be disposed on the second touch insulating layer 184. The second touch conductive layer can include a first sensor electrode 185a and a second sensor electrode 185b. The sensor electrode 185 can include the first sensor electrode 185a extending in the first direction DR1 (see FIG. 1) and the second sensor electrode 185b extending in the second direction DR2 (see FIG. 1) different from the first direction DR1.

The bridge electrode 182 can be electrically connected to the first sensor electrode 185a through contact holes formed in the first touch insulating layer 183 and the second touch insulating layer 184. The second sensor electrode 185b can be disposed on the second touch insulating layer 184. For example, the first sensor electrode 185a and the bridge electrode 182 can extend in the first direction DR1 (see FIG. 1).

The sensor electrode 185 and the bridge electrode 182 can include a metallic material. For example, the sensor electrode 185 and the bridge electrode 182 can be formed of titanium (Ti), nickel (Ni), aluminum (Al), or an alloy thereof and formed of a triple layer, such as titanium (Ti)/aluminum (Al)/titanium (Ti), but the embodiments of the present disclosure are not limited thereto.

A filter insulating layer 114 can be disposed on the second touch conductive layer. The filter insulating layer 114 can be formed of an inorganic insulation material, such as silicon nitride (SiNₓ) or silicon oxide (SiOₓ), but the embodiments of the present disclosure are not limited thereto.

The black matrix BM can be disposed on the filter insulating layer 114. For example, the black matrix BM can be disposed on a portion of the filter insulating layer 114. The black matrix BM can include a black-based material. For example, the black matrix BM can include a light-blocking material or a light-absorbing material. For example, the black matrix BM can be formed of a material including a black pigment, a black dye, etc. The black matrix BM can be configured to cover the bridge electrode 182 and the sensor electrode 185. The bridge electrode 182 and the sensor electrode 185 can overlap the black matrix BM. Accordingly, the bridge electrode 182 and the sensor electrode 185 can be prevented or reduced from being visible from the outside. For example, a width of the black matrix BM can be smaller than a width of the bank 154.

The color filters 191, 192, and 193 can be disposed on the black matrix BM.

The color filters 191, 192, and 193 can be disposed on the first to third sub-pixels PX1, PX2, and PX3, respectively, and can block specific colors from light emitted from the light-emitting area EA1, EA2, and EA3 of the sub-pixels PX1, PX2, and PX3. A first color filter 191 can be provided as a first color filter, a second color filter 192 can be provided as a second color filter, and a third color filter 193 can be provided as a third color filter.

A first color filter 191 can be provided to block light of other colors not including red (R) light. In this case, the first color filter 191 can be provided as a red color filter. A second color filter 192 can be provided to block light of other colors not including green (G) light. In this case, the second color filter 192 can be provided as a green color filter. A third color filter 193 provided in the third sub-pixel PX3 can be provided to block light of other colors not including blue (B) light. In this case, the third color filter 193 can be provided as a blue color filter. However, the embodiments of the present disclosure are not limited thereto.

For example, each color filter 191, 192, or 193 can come into direct contact with side and upper surfaces of the black matrix BM. Specifically, each color filter 191, 192, or 193 can come into direct contact with side and a portion of upper surfaces of the black matrix BM, but the embodiments of the present disclosure are not limited thereto. For example, each color filter 191, 192, or 193 can be spaced apart from the boundaries of adjacent sub-pixels PX1, PX2, and PX3, but the embodiments of the present disclosure are not limited thereto, and the color filters 191, 192, and 193 can overlap each other in the thickness direction.

The planarization layer OC can be disposed on the color filters 191, 192, and 193. The planarization layer OC can serve to planarize a step formed by the color filters 191, 192, and 193. For example, the planarization layer OC can include an organic insulation material. For example, the planarization layer OC can be formed integrally across the sub-pixels PX1, PX2, and PX3.

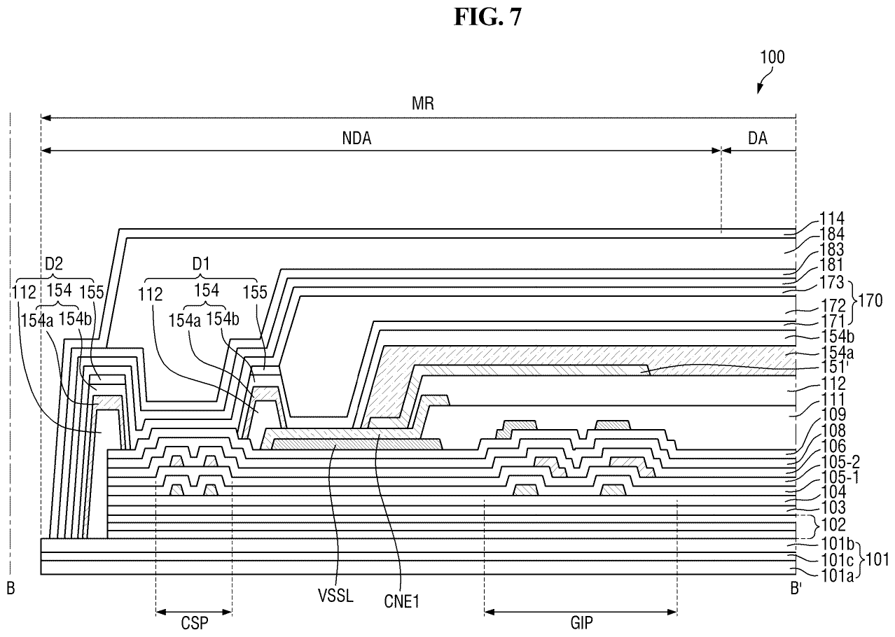

FIG. 7 is a cross-sectional view along line B-B′ in FIG. 1.

Referring to FIG. 7, at least one of the panel inorganic layers 102, 103, 104, 105-1, 105-2, 106, 108, and 109 may not extend to the end portion of the substrate 101. For example, the at least one of the panel inorganic layers 102, 103, 104, 105-1, 105-2, 106, 108, and 109 can expose the end portion of the substrate 101, but the embodiments of the present disclosure are not limited thereto.

The display panel 100 according to one example embodiment can further include the crack sensing pattern CSP, the low-potential voltage line VSSL, and the gate driving unit GIP. The gate driving unit GIP can be configured, for example, in the form of a driving chip (IC), but is not limited thereto. As described above in FIG. 1, the low-potential voltage line VSSL can be located between the crack sensing pattern CSP and the display area DA, and the gate driving unit GIP can be located between the low-potential voltage line VSSL and the display area DA.

For example, as illustrated in FIG. 7, the gate driving unit GIP can be formed of a conductive layer located on the same layer as the first gate electrode 122 (see FIG. 3), a conductive layer located on the same layer as the second light-shielding layer 136 (see FIG. 3), or a conductive layer located on the same layer as the first source electrode 121, but the embodiments of the present disclosure are not limited thereto.

For example, the crack sensing pattern CSP can be disposed between a first dam D1 and a second dam D2. The crack sensing pattern CSP can be formed of a conductive layer located on the same layer as the first gate electrode 122 (see FIG. 3) or a conductive layer located on the same layer as the second light-shielding layer 136 (see FIG. 3), but the embodiments of the present disclosure are not limited thereto. For example, the crack sensing pattern CSP can include a conductive layer located on the same layer as the first source electrode 121, but the embodiments of the present disclosure are not limited thereto.

The low-potential voltage line VSSL can be disposed between the crack sensing pattern CSP and the gate driving unit GIP. The low-potential voltage line VSSL can be formed of a conductive layer located on the same layer as the first source electrode 121, but the embodiments of the present disclosure are not limited thereto.

The first protective layer 111 can cover the gate driving unit GIP, partially cover one end portion of the low-potential voltage line VSSL, and expose the other end portion of the low-potential voltage line VSSL. The first protective layer 111 can cover a portion of an upper surface of the low-potential voltage line VSSL which is adjacent to one end portion. In the present disclosure, the one end portion can refer to an area of a certain component, which is located in a direction from the non-display area NDA toward the display area DA, and the other end portion can refer to an area of the certain component, which is located in a direction from the display area DA toward the non-display area NDA.

A first connection electrode CNE1 located on the same layer as the connection electrode 145 can be disposed on the first protective layer 111. The first connection electrode CNEI can be directly connected to an area of the low-potential voltage line VSSL, which is exposed by the first protective layer 111. The first connection electrode CNE1 can cover the other end portion of the low-potential voltage line VSSL, but the embodiments of the present disclosure are not limited thereto. The first connection electrode CNE1 can cover another portion of an upper surface of the low-potential voltage line VSSL which is adjacent to the other end portion.

The second protective layer 112 can be disposed on the first connection electrode CNE1. The second protective layer 112 can come into direct contact with and cover one end portion of the first connection electrode CNE1 and expose the other end portion of the first connecting electrode CNE1. The second protective layer 112 can cover a portion of the second protective layer 112.

The second protective layer 112 can form a first layer of the first dam D1 and a first layer of the second dam D2. The first dam D1 can overlap, for example, the low-potential voltage line VSSL and cover the other end portion of the low-potential voltage line VSSL. The first dam D1 can come into direct contact with the first connection electrode CNE1 and cover the other end portion of the first connection electrode CNE1. The second protective layer 112 forming the first layer of the second dam D2 can come into direct contact with the exposed side surfaces of at least one of the panel inorganic layers 102, 103, 104, 105, 106, 107, and 109 and can come into direct contact with the upper surface of the substrate 101, but the embodiments of the present disclosure are not limited thereto. The second protective layer 112 can overlap the gate driving unit GIP. In the present disclosure, the dam is, for example, provided as two dams, but the dam can be provided as three or more dams or one dam.

A low-potential connection electrode 151′ located on the same layer as the anode electrode 151 (see FIG. 3) can be disposed on the first connection electrode CNE1 exposed by the second protective layer 112 and the second protective layer 112. The low-potential connection electrode 151′ can be electrically connected to the first connection electrode CNE1 exposed by the second protective layer 112. The low-potential connection electrode 151′ can be electrically connected to the cathode electrode 153 (see FIG. 3) described above in FIG. 3. For example, the low-potential connection electrode 151′ can be disposed on a portion of the second protective layer 112.

The bank 154 can be disposed on the low-potential connection electrode 151′ and the second protective layer 112. For example, the bank 154 can be disposed on another portion of the second protective layer 112. The bank 154 can overlap the gate driving unit GIP, overlap the low-potential connection electrode 151′, and cover the other end portion of the low-potential connection electrode 151′. The bank 154 can completely cover the low-potential connection electrode 151′, but the embodiments of the present disclosure are not limited thereto. The bank 154 can expose a central portion and the other end portion of the first connection electrode CNE1, but the embodiments of the present disclosure are not limited thereto. The first bank 154a of the bank 154 can form a second layer of the first dam DI and a second layer of the second dam D2. In each dam D1 or D2, the first bank 154a can overlap the second protective layer 112 forming the first layer and completely cover the second protective layer 112, but the embodiments of the present disclosure are not limited thereto. In the second dam D2, the first bank 154a can come into contact with the side surfaces of the second protective layer 112 and the upper surface of the substrate 101, but the embodiments of the present disclosure are not limited thereto. The second bank 154b can form a third layer of the dam DI or D2. The second bank 154b forming the third layer of each dam D1 or D2 can overlap the first bank 154a forming the second layer and completely cover the first bank 154a, but the embodiments of the present disclosure are not limited thereto. In the second dam D2, the second bank 154b can come into contact with the side surfaces of the first bank 154a and the upper surface of the substrate 101, but the embodiments of the present disclosure are not limited thereto.

The spacer 155 can form a fourth layer of the first dam D1 and a fourth layer of the second dam D2. In each of the first dam D1 or the second dam D2, the spacer 155 can overlap the second bank 154b forming the third layer. In the second dam D2, the spacer 155 forming the fourth layer can overlap the second bank 154b forming the third layer.

The encapsulation part 170 can be disposed on the spacer 155. For example, the encapsulation part 170 can include a first encapsulation layer 171, a second encapsulation layer 172 disposed on the first encapsulation layer 171, and a third encapsulation layer 173 disposed on the second encapsulation layer 172, but the embodiments of the present disclosure are not limited thereto.

The first encapsulation layer 171 can extend to the gate driving unit GIP, the low-potential voltage line VSSL, the first dam D1, and the second dam D2 and cover an outer surface of the second dam D2. The second encapsulation layer 172 can extend to the gate driving unit GIP, the low-potential voltage line VSSL. The second encapsulation layer 172 can end at the first dam D1. The second encapsulation layer 172 can overlap the gate driving unit GIP and the low-potential voltage line VSSL. The third encapsulation layer 173 can extend to the gate driving unit GIP, the low-potential voltage line VSSL, the first dam D1, and the second dam D2 and come into direct contact with the first encapsulation layer 171 on the first dam D1, the crack sensing pattern CSP, and the second dam D2.

The touch buffer layer 181 and the first touch insulating layer 183 can extend to the gate driving unit GIP, the low-potential voltage line VSSL, the first dam D1, and the second dam D2 and cover the outer surface of the second dam D2. The second touch insulating layer 184 can extend to the gate driving unit GIP, the low-potential voltage line VSSL, the first dam D1, and the crack sensing pattern CSP and end on the second dam D2, but the embodiments of the present disclosure are not limited thereto.

The filter insulating layer 114 can extend to the gate driving unit GIP, the low-potential voltage line VSSL, the first dam D1, and the second dam D2 and come into direct contact with an outer surface of the second touch insulating layer 184, but the embodiments of the present disclosure are not limited thereto.

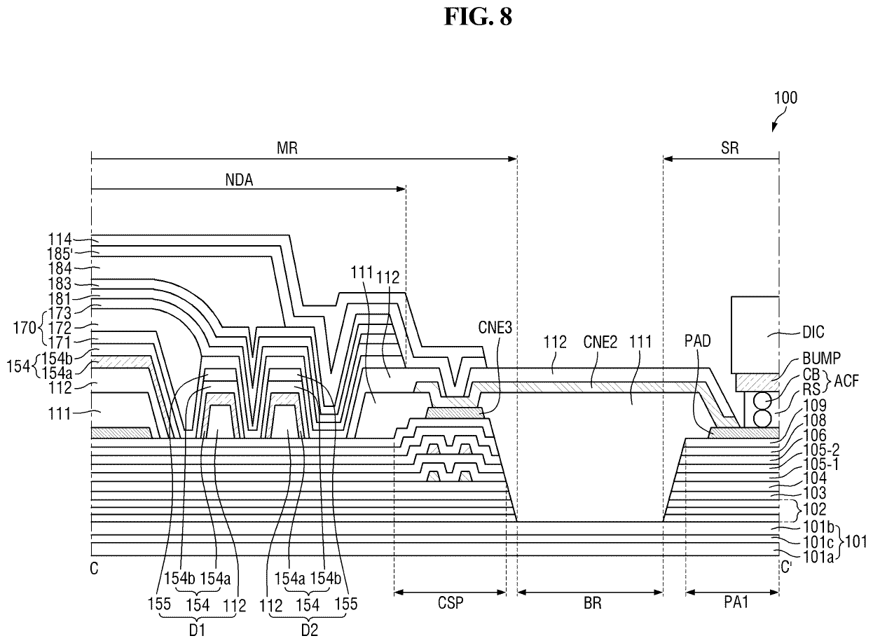

FIG. 8 is a cross-sectional view along line C-C′ in FIG. 1.

Referring to FIGS. 3, 7, and 8, the bending region BR can be disposed between the sub-region SR and the crack sensing pattern CSP. In the bending region BR, the layers disposed on the substrate 101 can be removed. For example, in the bending region BR, the panel inorganic layers 102, 103, 104, 105, 106, 107, and 109 can be removed to expose the upper surface of the substrate 101, but the embodiments of the present disclosure are not limited thereto.

In the first pad area PA1, a pad electrode PAD disposed on the same layer as the first source electrode 121 (see FIG. 3) can be disposed, and a third connection electrode CNE3 disposed on the same layer as the first source electrode 121 (see FIG. 3) can be disposed on the crack sensing pattern CSP.

The first protective layer 111 can be disposed on the pad electrode PAD and the third connection electrode CNE3. The first protective layer 111 can be disposed in the bending region BR, and in the bending region BR, the first protective layer 111 can be disposed on the substrate 101, the first protective layer 111 can come into direct contact with the upper surface of the substrate 101 and in the bending region BR, the first protective layer 111 can come into direct contact with the side surfaces of the panel inorganic layers 102, 103, 104, 105, 106, 107, and 109.

A second connection electrode CNE2 can be disposed on the first protective layer 111, and the second connection electrode CNE2 can be disposed on the same layer as the connection electrode 145 (see FIG. 3), but the embodiments of the present disclosure are not limited thereto. The second connection electrode CNE2 can electrically connect the pad electrode PAD to the third connection electrode CNE3. The second connection electrode CNE2 can be disposed on the bending region BR and can also be disposed on the first pad area PA1 and the crack sensing pattern CSP. For example, the second connection electrode CNE2 can be disposed on the first protective layer 111 in the bending region BR.

The data driving unit DIC can be disposed on the pad electrode PAD. The data driving unit DIC can include a bump BUMP, an anisotropic conductive film ACF can be disposed between the pad electrode PAD and the bump BUMP, and the anisotropic conductive film ACF can electrically connect the pad electrode PAD to the bump BUMP. The anisotropic conductive film ACF can include a resin RS and a plurality of conductive balls CB dispersed in the resin RS. The pad electrode PAD and the bump BUMP can be electrically connected through the conductive balls CB.

The second protective layer 112 can be disposed on the second connection electrode CNE2. The second protective layer 112 can expose the pad electrode PAD.

The first and third encapsulation layers 171 and 173 of the encapsulation part 170 can extend until before the bending region BR. For example, the first and third encapsulation layers 171 and 173 can extend until before the crack sensing pattern CSP, but the embodiments of the present disclosure are not limited thereto, and the first and third encapsulation layers 171 and 173 can also overlap the crack sensing pattern CSP. The first and third encapsulation layers 171 and 173 may not be disposed in the bending region BR.

The touch buffer layer 181 and the first touch insulation layer 183 can extend until before the bending region BR. For example, the touch buffer layer 181 and the first touch insulating layer 183 can extend until before the crack sensing pattern CSP, but the embodiments of the present disclosure are not limited thereto, and the touch buffer layer 181 and the first touch insulating layer 183 can also overlap the crack sensing pattern CSP. The touch buffer layer 181 and the first touch insulation layer 183 may not be disposed in the bending region BR.

The second touch insulating layer 184 can overlap the first dam D1 and the second dam D2. The second touch insulating layer 184 may not be disposed outside the second dam D2, but the embodiments of the present disclosure are not limited thereto. The second touch insulating layer 184 may not be disposed in the bending region BR.

A touch connection line 185′ can be electrically connected to the second connection electrode CNE2. The touch connection line 185′ can serve to provide a signal applied from the pad electrode PAD and the second connection electrode CNE2 to the first sensor electrode 185a or the second sensor electrode 185b described above in FIG. 3. The touch connection line 185′ can be located on the same layer as the second touch conductive layer (the first sensor electrode 185a of FIG. 3), but the embodiments of the present disclosure are not limited thereto, and the touch connection line 185′ can be located on the same layer as the first touch conductive layer (the bridge electrode 182 of FIG. 3) or formed of two first and second touch conductive layers, but the embodiments of the present disclosure are not limited thereto. The touch connection line 185′ may not be disposed in the bending region BR.

The filter insulating layer 114 can be disposed on the touch connection line 185′, and the filter insulating layer 114 may not be disposed in the bending region BR.

FIG. 9 is a planar arrangement view of sub-pixels of a display area in FIG. 1.

Referring to FIG. 9, the display panel 100 according to one example embodiment can include a plurality of sub-pixels PX1, PX2, and PX3. First sub-pixels PX1 (or a first sub-pixel column) can be disposed to be spaced apart from each other in the second direction DR2, second sub-pixels PX2 (or a second sub-pixel column) can be disposed to be spaced apart from each other in the second direction DR2, and third sub-pixels PX3 (or a third sub-pixel column) can be disposed to be spaced apart from each other in the second direction DR2. The sub-pixel columns can be disposed adjacent to each other in the first direction DR1, but the embodiments of the present disclosure are not limited thereto.

The anode electrode 151 can be exposed by the banks 154a and 154b. The anode electrode 151 exposed by the banks 154a and 154b can have flat surface shape. For example, the flat surface shape of the anode electrode 151 exposed by the banks 154a and 154b can be circular, but the embodiments of the present disclosure are not limited thereto.

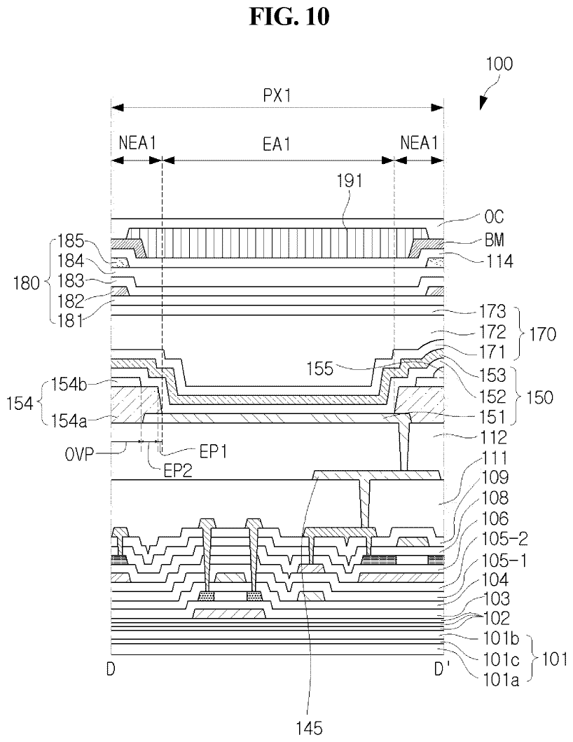

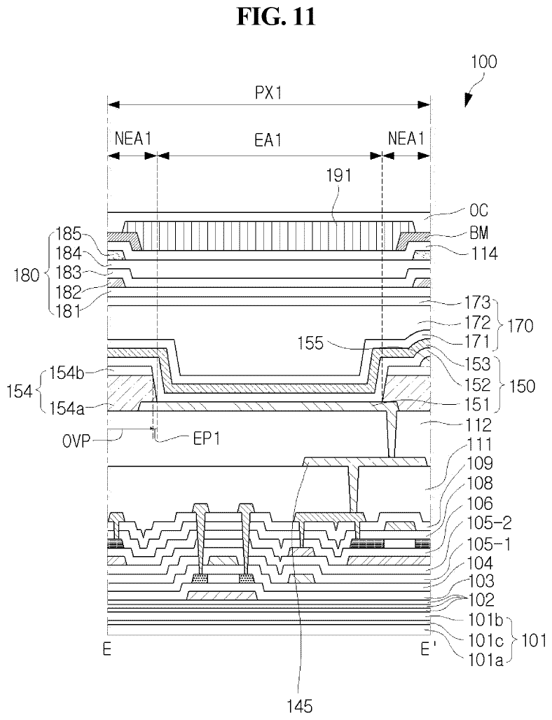

The first bank 154a can be exposed by the second bank 154b. FIG. 9 illustrates only the area of the first bank 154a exposed by the second bank 154b, but in reality, the first bank 154a can further include an area overlapping the second bank 154b (overlapping portions OVP of FIGS. 10 and 11).

The first bank 154a can include a first exposed portion EP1 exposed by the second bank 154b. The first exposed portion EP1 can surround the anode electrode 151 exposed by the banks 154a and 154b in a plan view. For example, the first exposed portion EP1 can completely surround the anode electrode 151 exposed by the banks 154a and 154b in a plan view, but the embodiments of the present disclosure are not limited thereto. The first exposed portion EP1 can overlap the anode electrode 151 and surround areas exposed by the banks 154a and 154b in a plan view.

A second exposed portion EP2 can protrude outward from the first exposed portion EP1 in a plan view. For example, the second exposed portion EP2 can be provided as a plurality of second exposed portions, and the plurality of second exposed portions EP2 can be disposed to be spaced apart from each other in a plan view. FIG. 9 exemplarily illustrates that the second exposed portion EP2 protrudes outward from the first exposed portion EP1 in a direction between the first direction DR1 and the second direction DR2, and the number of second exposed portions EP2 is illustrated as four, but the embodiments of the present disclosure are not limited thereto. The second exposed portions EP2 can be spaced apart at regular intervals, but the embodiments of the present disclosure are not limited thereto. In some example embodiments, the second exposed portion EP2 can be disposed in the first direction DR1 or the second direction DR2. For example, the second exposed portion EP2 can be disposed in the first direction DR1, the second direction DR2 or a direction between the first direction DR1 and the second direction DR2.

For example, the flat surface shape of the second exposed portion EP2 can be substantially an equilateral triangle or a right triangle, but the embodiments of the present disclosure are not limited thereto. For example, each of side surfaces of the second exposed portion EP2 can be about 5 μm, but the embodiments of the present disclosure are not limited thereto. In some example embodiments, a length of a lower surface of the second exposed portion EP2 in contact with the first exposed portion EP1 can be about 4 μm, and a length of the side surface thereof can be about 8 μm, but the embodiments of the present disclosure are not limited thereto.

For example, the outline of the flat surface shape of the first bank 154a exposed by the second bank 154b can include at least one protrusion protruding outward. The protrusion can be the same as the second exposed portion EP2.

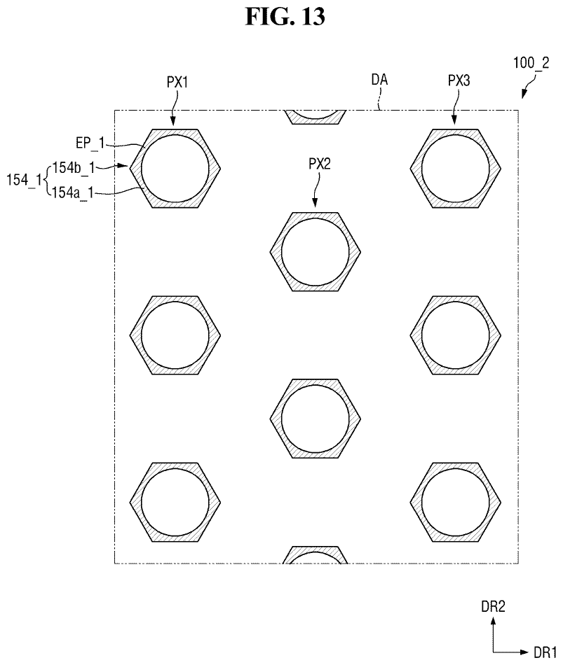

In the banks 154a and 154b according to one example embodiment, since the first bank 154a includes the second exposed portion EP2 exposed by the second bank 154b and disposed between the overlapping portion OVP (see FIG. 10) and the first exposed portion EP1 and the second exposed portions EP2 are disposed to be spaced apart from each other (a protrusion or angled structure is applied to the bank), it is possible to improve the spreadability of the second encapsulation layer (or the organic encapsulation layer). FIG. 9 illustrates a case in which the protrusion structure is applied to the bank. In the present disclosure, when the protrusion structure or the angled structure is applied to the bank, it means that the shape formed by the outlines of the first exposed portion EP1 and the second exposed portion EP2 of the bank have a protrusion shape or an angled shape (or a polygonal shape). In FIG. 13, the shape formed by the outline of an exposed portion EP_1 can be an angled shape.

Referring to FIG. 9, the flat surface shape and flat surface arrangement of the second exposed portion EP2 of all sub-pixels PX1, PX2, and PX3 can be the same, but the embodiments of the present disclosure are not limited thereto.

FIG. 10 is a cross-sectional view along line D-D′ in FIG. 9. FIG. 11 is a cross-sectional view along line E-E′ in FIG. 9. FIG. 10 illustrates cross-sectional shapes of the banks 154a and 154b including the second exposed portion EP2, and FIG. 11 illustrates cross-sectional shapes of the banks 154a and 154b in which the second exposed portion EP2 is not disposed.

Referring to FIGS. 9 to 11, the first bank 154a can cover the periphery of the anode electrode 151 and expose the central portion of the anode electrode 151. The second bank 154b can be disposed on the first bank 154a and can overlap the first bank 154a. The second bank 154b can expose a part of the first bank 154a. For example, the first bank 154a can include the overlapping portion OVP overlapping the second bank 154b and the exposed portions EP1 and EP2 exposed by the second bank 154b. The exposed portions EP1 and EP2 can include the first exposed portion EP1 protruding from the end of the second bank 154b toward the central portion of the anode electrode 151, and the second exposed portion EP2 between the first exposed portion EP1 and the overlapping portion OVP. The first exposed portion EP1 can include an inner surface (or side surfaces) of the first bank 154a. An upper surface of the second exposed portion EP2 can come into direct contact with the organic layer 152, and side surfaces of the first exposed portion EP1 can come into direct contact with the organic layer 152.

Referring to FIGS. 10 and 11, a distance between the end of the black matrix BM and the boundary between the first light-emitting area EA1 and the first non-light-emitting area NEA1 can be longer than a distance between the end of the bank 154 and the boundary between the first light-emitting area EA1 and the first non-light-emitting area NEA1. The end of the bank 154 can be aligned with the boundary between the first light-emitting area EA1 and the first non-light-emitting area NEA1, but the embodiments of the present disclosure are not limited thereto. The end of the black matrix BM can be spaced apart from the boundary between the first light-emitting area EA1 and the first non-light-emitting area NEA1. The end of the black matrix BM can be located farther from the first light-emitting area EA1 than the end of the first bank 154a. In the case of the display panel 100 according to one example embodiment, the bank 154 (the first bank 154a) can include a black-based material, and since the spacing distance between the end of the black matrix BM and the boundary between the first light-emitting area EA1 and the first non-light-emitting area NEA I can be longer than the spacing distance between the end of the bank 154 and the boundary between the first light-emitting area EA1 and the first non-light-emitting area NEA1, light emitted from the first light-emitting area EA1 can be emitted upward with a greater viewing angle as much as a spacing space between the end of the black matrix BM and the boundary between the first light-emitting area EA1 and the first non-light-emitting area NEA1. Accordingly, it is possible to minimize or reduce a reduction in luminance according to a viewing angle. However, when the spacing distance between the end of the black matrix BM and the boundary between the first light-emitting area EA1 and the first non-light-emitting area NEA1 is longer than the spacing distance between the end of the bank 154 and the boundary between the first light-emitting area EA1 and the first non-light-emitting area NEA1 and the bank 154 is formed of a transparent material, light incident from the outside can be reflected by the bank 154, resulting in visible ring-shaped spots. However, in the case of the display panel 100 according to one example embodiment, the light incident from the outside can be absorbed or blocked by the bank 154 including a black-based material, thereby preventing or reducing the occurrence of the ring-shaped spots.

For example, as illustrated in FIGS. 10 and 11, the black matrix BM may not overlap the first exposed portion EP1, but the embodiments of the present disclosure are not limited thereto. The end of the black matrix BM can be located farther from the first light-emitting area EA1 than the end of the first bank 154a, and as illustrated in FIG. 10, the black matrix BM can overlap the second exposed portion EP2. The black matrix BM can overlap the overlapping portion OVP.

The second encapsulation layer 172 can be disposed on the first encapsulation layer 171 and can include an organic insulation material. Since the second encapsulation layer 172 includes an organic insulation material and has a great thickness, the second encapsulation layer 172 applied to the first light-emitting area EA1 can have difficulty in spreading to the first non-light-emitting area NEA1. In particular, as illustrated in FIG. 11, when the inner surfaces (or the side surfaces) of the first bank 154a and the second bank 154b are aligned to form a step, it can be very difficult for the second encapsulation layer 172 to spread to the first non-light-emitting area NEA1 beyond the step.

When a structure, such as a protrusion film, is applied to a surface of the first encapsulation layer 171, a surface tension between the second encapsulation layer 172 and the first encapsulation layer 171 can increase, and thus the second encapsulation layer 172 can spread beyond the corresponding step, but in this case, the function of blocking external moisture by the first encapsulation layer 171 can be degraded. In this case, the second encapsulation layer 172 can spread to the first non-light-emitting area NEA1 beyond the step, the function of blocking external moisture by the first encapsulation layer 171 can be degraded.

However, according to the display panel 100 according to one example embodiment, the first bank 154a can include the second exposed portion EP2 exposed by the second bank 154b and disposed between the overlapping portion OVP (see FIG. 10) and the first exposed portion EP1, and the second exposed portions EP2 can be disposed to be spaced apart from each other (a protrusion structure can be applied to the bank). For example, as illustrated in FIG. 10, by arranging the inner surface of the first bank 154a and the inner surface of the second bank 154b to be spaced apart from each other on the area in which the second exposed portion EP2 is applied, it is possible to minimize or reduce a step difference between the inner surfaces of the first and second banks 154a and 154b in FIG. 11. Accordingly, it is possible to improve the spreadability of the second encapsulation layer (or the organic encapsulation layer).

Hereinafter, a display device according to other embodiments will be described. In the following embodiments, the detailed description of the reference numerals or components described in FIGS. 1 to 11 will be omitted or briefly given, or the overlapping descriptions thereof will be omitted or briefly given.

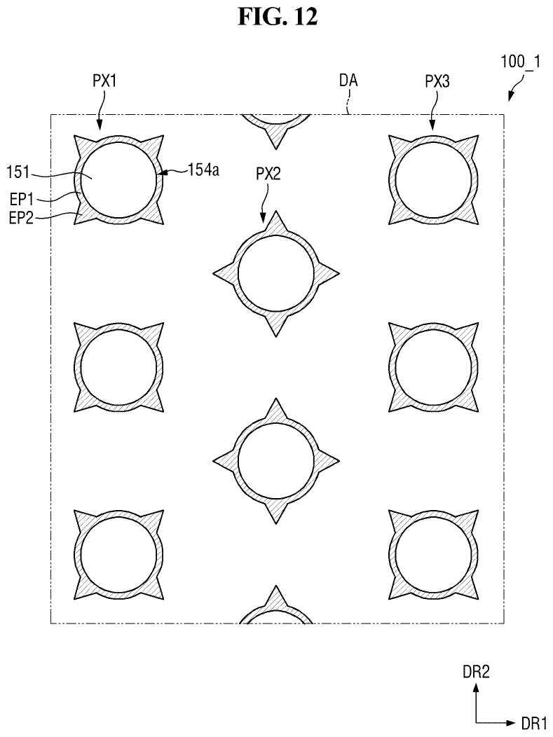

FIG. 12 is a flat surface arrangement view of sub-pixels of a display area of a display device according to another example embodiment of the present disclosure.

Referring to FIG. 12, a display panel 100_1 according to the present embodiment differs from the display panel 100 according to FIG. 9 in that the arrangement of the second exposed portion EP2 can be different in each sub-pixel PX1, PX2, or PX3.

More specifically, the display panel 100_1 differs from the display panel 100 of FIG. 9 in that the arrangement of the second exposed portion EP2 of FIG. 9 is applied to the first sub-pixel PX1 (the first sub-pixel row), while the second exposed portions EP2 of the second sub-pixel PX2 extend in the first direction DR1 or the second direction DR2. For example, the arrangement of the second exposed portion EP2 of FIG. 9 is applied to the first sub-pixel PX1 (the first sub-pixel row) and the third sub-pixels PX3 (or a third sub-pixel column), while the second exposed portions EP2 of the second sub-pixel PX2 extend in the first direction DR1 or the second direction DR2. For example, the second exposed portions EP2 of the first sub-pixel PX1 (the first sub-pixel row) and the third sub-pixels PX3 (or a third sub-pixel column) protrude in a direction between the first direction DR1 and the second direction DR2.

According to the present embodiment, since the arrangement of the second exposed portion EP2 is different in each sub-pixel PX1, PX2, or PX3, it is possible to minimize or reduce a pattern from being visible from the outside due to the arrangement of the second exposed portion EP2.

Since the remaining parts have been described above in FIGS. 1 to 11, the detailed descriptions thereof will be omitted or briefly given below.

FIG. 13 is a flat surface arrangement view of sub-pixels of a display area of a display device according to yet another example embodiment.

Referring to FIG. 13, a first bank 154a_1 of the bank 154_1 of a display panel 100_2 according to the present embodiment differs from the display panel 100 according to FIG. 9 in that it includes the exposed portion EP_1 exposed by a second bank 154b_1.

More specifically, the first bank 154a_1 can include the exposed portion EP_1, and the outline of the flat surface shape of the exposed portion EP_1 can include a plurality of bent portions. FIG. 13 illustrates the outline of the exposed portion EP_1 including six bent portions, but the above outline can include 1 to 5 or 7 or more bent portions.

In the present embodiment, the first bank 154a_1 can include an exposed portion EP2_1 exposed by the second bank 154b_1, and the bent portions of the outline of the exposed portion EP2_1 can be disposed to be spaced apart from each other (an angled structure can be applied to the bank). Accordingly, it is possible to improve the spreadability of the second encapsulation layer (or the organic encapsulation layer).

Since the remaining parts have been described above in FIGS. 1 to 11, the detailed descriptions thereof will be omitted or briefly given below.

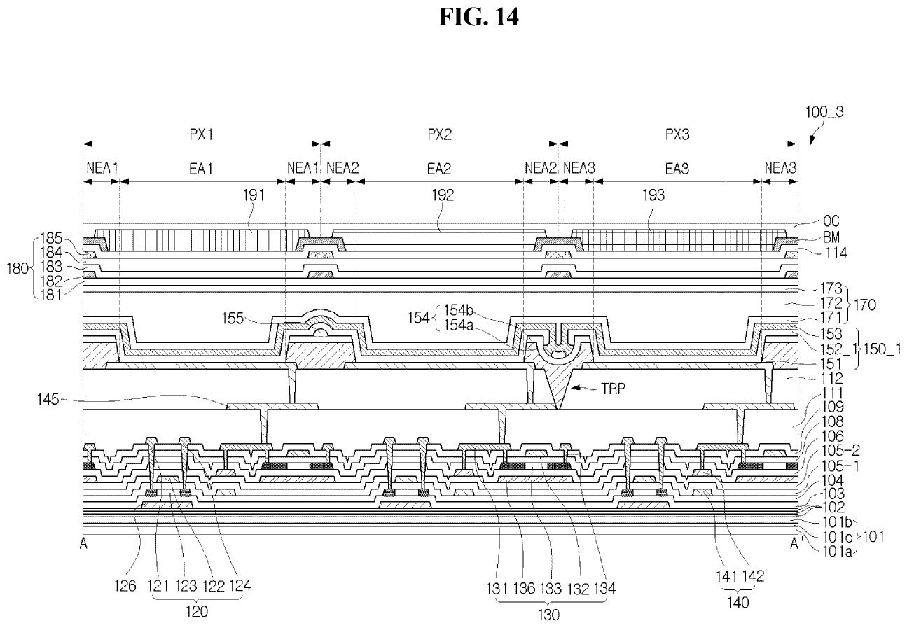

FIG. 14 is a cross-sectional view of a display device according to yet another example embodiment of the present disclosure.

Referring to FIG. 14, a display panel 100_3 of the display device according to the present embodiment differs from the display panel 100_1 according to FIG. 3 in that the organic layer 152_1 of a light-emitting part 150_1 can be physically separated from a trench TRP.

According to the present embodiment, since the second protective layer 112 on the non-light-emitting areas NEA1, NEA2, and NEA3 includes the trench TRP, the organic layer 152_1 formed integrally across the sub-pixels PX1, PX2, and PX3 can be separated, thereby preventing or reducing a lateral leakage current between adjacent sub-pixels PX1, PX2, and PX3.

Since the remaining parts have been described above in FIG. 3, the detailed descriptions thereof will be omitted or briefly given.

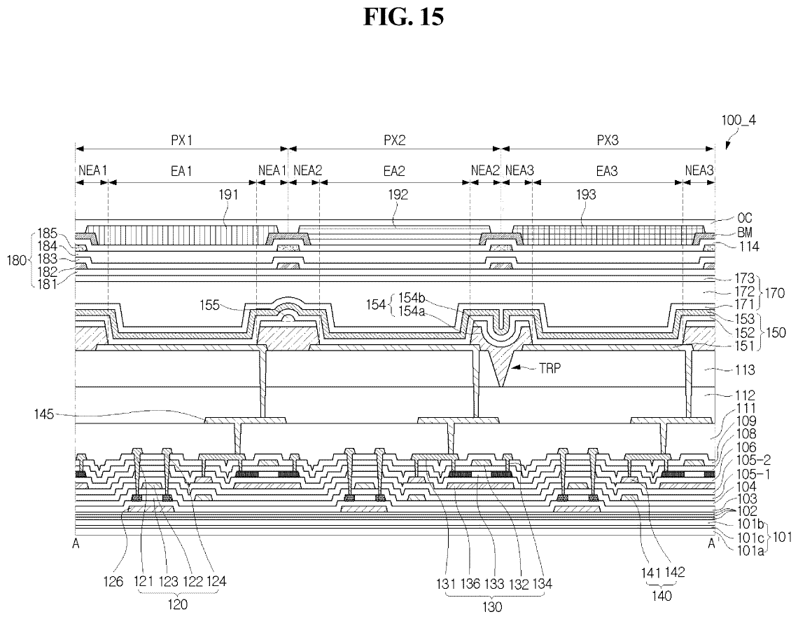

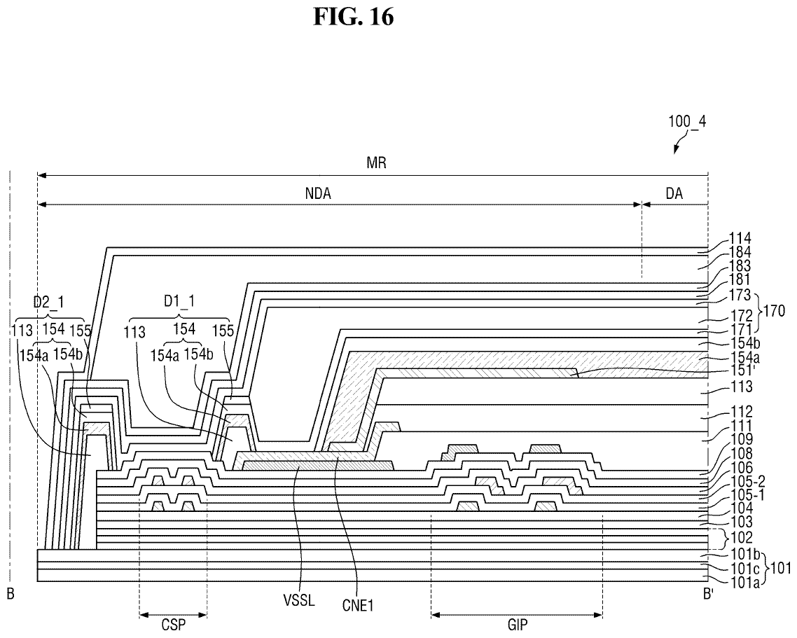

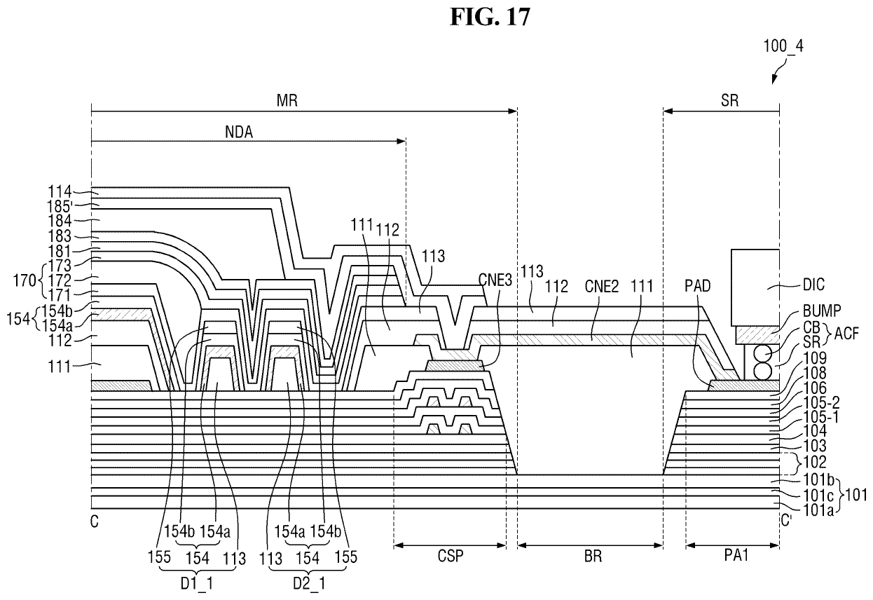

FIG. 15 is a cross-sectional view of a display device according to yet another example embodiment of the present disclosure. FIG. 16 is a cross-sectional view of a display device according to yet another example embodiment of the present disclosure. FIG. 17 is a cross-sectional view of a display device according to yet another example embodiment of the present disclosure.

Referring to FIGS. 15 to 17, a display panel 100_4 of the display device according to the present embodiment differs from the display panel 100 according to FIGS. 3, 7, and 8 in that it can further include a third protective layer 113 on the second protective layer 112.

More specifically, the display panel 100_4 according to the present embodiment can further include the third protective layer 113 between the second protective layer 112 and the anode electrode 151. For example, the third protective layer 113 can be disposed to surround the trench TRP. The third protective layer 113 and the trench TRP can be disposed on the second protective layer 112. A material of the third protective layer 113 can include at least one of materials exemplified as the material of the second protective layer 112, but the embodiments of the present disclosure are not limited thereto.

Referring to FIG. 15, the trench TRP can pass through the third protective layer 113 in the non-light-emitting areas NEA1, NEA2, and NEA3. The trench TRP may not pass through the second protective layer 112. For example, the trench TRP can be disposed to expose a portion of the second protective layer 112. The first bank 154a can come into direct contact with the upper surface of the second protective layer 112 in the trench TRP. For example, the first bank 154a can come into direct contact with the portion of the upper surface of the second protective layer 112 exposed by the trench TRP.

Each of a first dam D1_1 and a second dam D2_1 can include the third protective layer 113 as a first layer and may not include the second protective layer 112, but the embodiments of the present disclosure are not limited thereto.

Since the remaining parts have been described above in FIGS. 3, 7, and 8, the detailed descriptions thereof will be omitted or briefly given below.

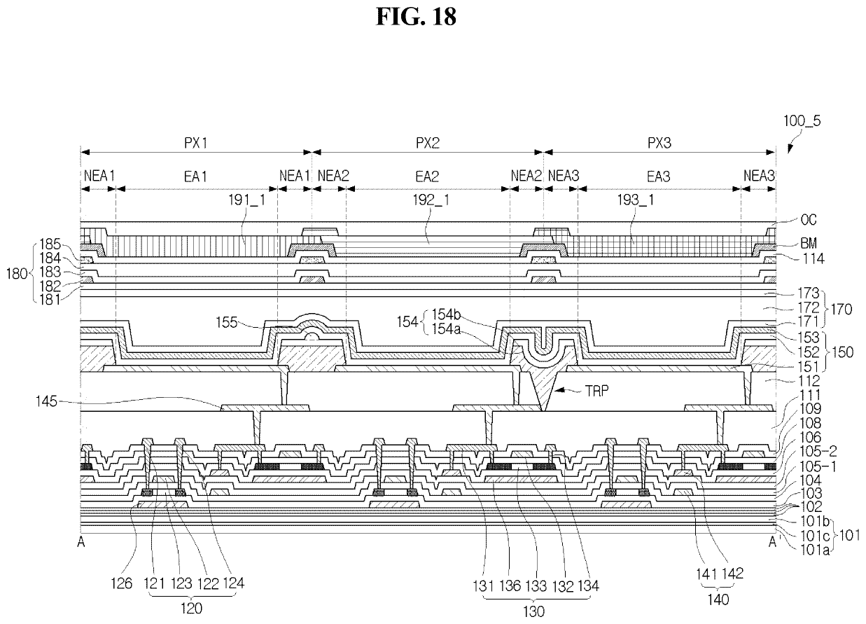

FIG. 18 is a cross-sectional view of a display device according to yet another example embodiment of the present disclosure.

Referring to FIG. 18, color filters 191_1, 192_1, and 193_1 of a display panel 100_5 of the display device according to the present embodiment differ from the display panel 100 according to FIG. 3 in that they can overlap each other in the non-light-emitting areas NEA1, NEA2, and NEA3. For example, the color filters 191_1, 192_1, and 193_1 can overlap each other at the boundaries between the sub-pixels.

FIG. 18 illustrates that a second color filter 192_1 is located at the top, a first color filter 191_1 is located under the second color filter 192_1, and lastly a third color filter 193_1 is located at the bottom in each non-light-emitting area NEA1, NEA2, or NEA3, but the stacking order of each color filter 191_1, 192_1, or 193_1 in the non-light-emitting areas NEA1, NEA2, and NEA3 can vary according to a process order.

Since the remaining parts have been described above in FIG. 3, the detailed descriptions thereof will be omitted or briefly given.

A display device according to various embodiments of the present disclosure can be described as follows.

A display device according to embodiments of the present disclosure includes a substrate including a display area including a plurality of sub-pixels, and a non-display area around the display area, an anode electrode disposed in each of the plurality of sub-pixels on the substrate, a bank disposed on the anode electrode, located at a boundary between adjacent sub-pixels, covering a periphery of an upper surface of the anode electrode, and including a first bank on the anode electrode and a second bank on the first bank, in which the first bank includes an overlapping portion overlapping the second bank, a first exposed portion exposed by the second bank and including a side surface, and a second exposed portion exposed by the second bank and disposed between the overlapping portion and the first exposed portion, the second exposed portion is provided as a plurality of second exposed portions, and the plurality of adjacent second exposed portions are spaced apart from each other in a plan view.

In the display device according to various embodiments of the present disclosure, the plurality of sub-pixels can include a first sub-pixel, a second sub-pixel, and a third sub-pixel, and the display device can further comprise an organic layer disposed on the anode electrode and the bank and disposed across the plurality of sub-pixels.

In the display device according to various embodiments of the present disclosure, the first bank can include a black-based material, and the second bank can include a transparent-based material.

In the display device according to various embodiments of the present disclosure, the organic layer can include a first light-emitting layer on the first sub-pixel, a second light-emitting layer on the second sub-pixel, and a third light-emitting layer on the third sub-pixel.

In the display device according to the example embodiments of the present disclosure, in each sub-pixel, each of the first light-emitting layer, the second light-emitting layer, and the third light-emitting layer can be stacked in two or more layers.

The display device according to various embodiments of the present disclosure can further include a cathode electrode on the organic layer, and a black matrix located at the boundary between the adjacent sub-pixels on the cathode electrode, in which a width of the black matrix can be smaller than a width of the first bank.

In the display device according to various embodiments of the present disclosure, an end of the black matrix can be closer to the boundary between the adjacent sub-pixels than an end of the first bank.

In the display device according to various embodiments of the present disclosure, the black matrix can overlap the second exposed portion.

The display device according to various embodiments of the present disclosure can further include a touch part on the cathode electrode, in which the touch part can include a bridge electrode, and a sensor electrode on the bridge electrode, and the black matrix can overlap the bridge electrode and the sensor electrode.

The display device according to various embodiments of the present disclosure can further include a color filter on the touch part and the black matrix, in which the color filter can include a first color filter on the first sub-pixel, a second color filter on the second sub-pixel, and a third color filter on the third sub-pixel.

In the display device according to various embodiments of the present disclosure, the first color filter, the second color filter, and the third color filter can overlap each other at the boundaries between the adjacent sub-pixels.

In the display device according to various embodiments of the present disclosure, the first color filter, the second color filter, and the third color filter can be spaced apart from the boundaries between the adjacent sub-pixels.

The display device according to various embodiments of the present disclosure can further include a first transistor between the substrate and the anode electrode, and a second transistor between the first transistor and the anode electrode.

The display device according to various embodiments of the present disclosure can further include a first protective layer between the second transistor and the anode electrode, a first connection electrode disposed on the first protective layer, and a second protective layer on the first connection electrode, in which the first connection electrode can electrically connect the second transistor to the anode electrode.

In the display device according to various embodiments of the present disclosure, the second protective layer can further include a trench overlapping the bank and passing through the second protective layer in a thickness direction.

In the display device according to various embodiments of the present disclosure, the trench can be configured to separate the organic layer disposed across the plurality of sub-pixels.

The display device according to various embodiments of the present disclosure can further include a third protective layer between the second protective layer and the anode electrode, in which the third protective layer can further include a trench overlapping the bank and passing through the third protective layer in a thickness direction.

In the display device according to various embodiments of the present disclosure, a pattern in which the plurality of second exposed portions of the first sub-pixel are disposed, a pattern in which the plurality of second exposed portions of the second sub-pixel are disposed and a pattern in which the plurality of second exposed portions of the third sub-pixel are disposed can be different from each other.

In the display device according to various embodiments of the present disclosure, a pattern in which the plurality of second exposed portions of the first sub-pixel are disposed can differ from a pattern in which the plurality of second exposed portions of the second sub-pixel are disposed.

A display device according to various embodiments of the present disclosure includes a substrate including a display area including a plurality of sub-pixels including a first sub-pixel, a second sub-pixel, and a third sub-pixel, and a non-display area around the display area, an anode electrode disposed in each of the plurality of sub-pixels on the substrate in the display area, and a bank disposed on the anode electrode in the display area, located at a boundary between adjacent sub-pixels, covering a periphery of an upper surface of the anode electrode, and including a first bank on the anode electrode and a second bank on the first bank, in which the first bank includes an overlapping portion overlapping the second bank, and an exposed portion exposed by the second bank, an outline of the exposed portion has a plurality of bent portions in a plan view, and the plurality of adjacent bent portions are spaced apart from each other in a plan view.

In the display device according to various embodiments of the present disclosure, the first bank can include a black-based material, and the second bank can include a transparent-based material.

In the display device according to various embodiments of the present disclosure, a pattern in which the plurality of bent portions of the first sub-pixel are disposed can differ from a pattern in which the plurality of bent portions of the second sub-pixel are disposed.

The display device according to various embodiments of the present disclosure can further include a cathode electrode on the organic layer, and a black matrix located at a boundary between the adjacent sub-pixels on the cathode electrode, in which a width of the black matrix can be smaller than a width of the first bank, and an end of the black matrix can be closer to the boundary between the adjacent sub-pixels than an end of the first bank.

In the display device according to the example embodiments, the bank can include the black-based material to absorb external light guided to the lower portion of the bank.

In the display device according to the example embodiments, the organic layer is formed integrally across all of sub-pixels, but, by forming the trench in the protective layer and guiding the organic layer to be separated from the trench, it is possible to prevent or reduce a lateral leakage current between adjacent sub-pixels.

In the display device according to the example embodiments, since the first bank includes the second exposed portion exposed by the second bank and disposed between the overlapping portion and the first exposed portion and the second exposed portions are disposed to be spaced apart from each other (the protrusion structure or the angled structure is applied to the bank), it is possible to improve spreadability of the second encapsulation layer (or the organic encapsulation layer).

In the display device according to the example embodiments, by applying the protrusion or angled structure to the bank, it is possible to improve the spreadability of the second encapsulation layer (or the organic encapsulation layer) even when the thickness of the second encapsulation layer (or the organic encapsulation layer) is reduced.

In the display device according to the example embodiments, by applying the protrusion or angled structure to the bank, it is possible to improve the spreadability of the second encapsulation layer (or the organic encapsulation layer) even when the slope of the side surface of the bank is large.

In the display device according to the example embodiments, by absorbing external light incident on the lower portion of the bank, it is possible to provide low-reflection display device.

According to one example embodiment, there is provided a display device including a substrate including a display area including a plurality of sub-pixels, and a non-display area around the display area; an anode electrode disposed in each of the plurality of sub-pixels on the substrate; a bank disposed on the anode electrode, located at a boundary between adjacent sub-pixels, covering a periphery of an upper surface of the anode electrode; an organic layer disposed on the anode electrode and the bank and disposed across the plurality of sub-pixels; and a protective layer disposed under the organic layer, and including a trench overlapping the bank and passing through the protective layer in a thickness direction.

In the display device according to the example embodiments, the trench can be configured to separate the organic layer disposed across the plurality of sub-pixels.

However, effects obtainable from the present disclosure are not limited to the above-described effects, and other effects that are not mentioned will be able to be clearly understood by those skilled in the art to which the present disclosure pertains from the following description.

Although the embodiments of the present disclosure have been described above with reference to the accompanying drawings, those skilled in the art to which the present disclosure pertains will be able to understand that the above-described technical configuration of the present disclosure can be carried out in other specific forms without changing the technical idea or essential features thereof. Accordingly, it should be understood that the above-described embodiments are illustrative and not restrictive in all respects. In addition, the scope of the present disclosure is described by the claims to be described below rather than the detailed description. In addition, the meaning and scope of the claims and all changed or modified forms derived from the equivalent concept should be construed as being included in the scope of the present disclosure.

### DESCRIPTION OF REFERENCE NUMERALS

1: display device
100, 100_1, 100_2, 100_3, 100_4, 100_5: display panel
D1, D2: dam

What is claimed is:

1. A display device comprising:
a substrate including a display area including a plurality of sub-pixels, and a non-display area adjacent to the display area;
an anode electrode disposed in each of the plurality of sub-pixels on the substrate;
a bank disposed on the anode electrode, located at a boundary between adjacent sub-pixels, covering a periphery of an upper surface of the anode electrode, and including a first bank on the anode electrode and a second bank on the first bank,
wherein the first bank includes:
an overlapping portion overlapping the second bank;
a first exposed portion exposed by the second bank and including a side surface; and
a second exposed portion exposed by the second bank and disposed between the overlapping and the first exposed portion,
the second exposed portion is provided as a plurality of second exposed portions, and the plurality of second exposed portions that are adjacent are spaced apart from each other in a plan view.

2. The display device of claim 1, wherein the plurality of sub-pixels include a first sub-pixel, a second sub-pixel, and a third sub-pixel, and
the display device further comprises an organic layer disposed on the anode electrode and the bank and disposed across the plurality of sub-pixels.

3. The display device of claim 1, wherein the first bank includes a black-based material, and the second bank includes a transparent-based material.

4. The display device of claim 2, wherein the organic layer includes a first light-emitting layer on the first sub-pixel, a second light-emitting layer on the second sub-pixel, and a third light-emitting layer on the third sub-pixel.

5. The display device of claim 4, wherein, in each sub-pixel, each of the first light-emitting layer, the second light-emitting layer, and the third light-emitting layer is stacked in two or more layers.

6. The display device of claim 2, further comprising:
a cathode electrode on the organic layer, and
a black matrix located at the boundary between the adjacent sub-pixels on the cathode electrode,
wherein a width of the black matrix is smaller than a width of the first bank.

7. The display device of claim 6, wherein an end of the black matrix is closer to the boundary between the adjacent sub-pixels than an end of the first bank.

8. The display device of claim 6, wherein the black matrix overlaps the second exposed portion of the first bank.

9. The display device of claim 6, further comprising:
a touch part on the cathode electrode,
wherein the touch part includes a bridge electrode and a sensor electrode on the bridge electrode, and
the black matrix overlaps the bridge electrode and the sensor electrode.

10. The display device of claim 9, further comprising:
a color filter on the touch part and the black matrix,
wherein the color filter includes a first color filter on the first sub-pixel, a second color filter on the second sub-pixel, and a third color filter on the third sub-pixel.

11. The display device of claim 10, wherein the first color filter, the second color filter, and the third color filter overlap each other at the boundaries between the adjacent sub-pixels.

12. The display device of claim 10, wherein the first color filter, the second color filter, and the third color filter are spaced apart from the boundaries between the adjacent sub-pixels.

13. The display device of claim 2, further comprising:
a first transistor between the substrate and the anode electrode; and
a second transistor between the first transistor and the anode electrode.

14. The display device of claim 13, further comprising:
a first protective layer between the second transistor and the anode electrode;
a first connection electrode disposed on the first protective layer; and
a second protective layer on the first connection electrode,
wherein the first connection electrode electrically connects the second transistor to the anode electrode.

15. The display device of claim 14, wherein the second protective layer further includes a trench overlapping the bank and passing through the second protective layer in a thickness direction.

16. The display device of claim 15, wherein the trench is configured to separate the organic layer disposed across the plurality of sub-pixels.

17. The display device of claim 14, further comprising:
a third protective layer between the second protective layer and the anode electrode,
wherein the third protective layer further includes a trench overlapping the bank and passing through the third protective layer in a thickness direction.

18. The display device of claim 2, wherein a pattern in which the plurality of second exposed portions of the first sub-pixel are disposed differs from a pattern in which the plurality of second exposed portions of the second sub-pixel are disposed.

19. The display device of claim 2, wherein a pattern in which the plurality of second exposed portions of the first sub-pixel are disposed, a pattern in which the plurality of second exposed portions of the second sub-pixel are disposed and a pattern in which the plurality of second exposed portions of the third sub-pixel are disposed are different from each other.

20. A display device comprising:
a substrate including a display area including a plurality of sub-pixels including a first sub-pixel, a second sub-pixel, and a third sub-pixel, the substrate further including a non-display area adjacent to the display area;
an anode electrode disposed in each of the plurality of sub-pixels on the substrate in the display area;
a bank disposed on the anode electrode, located at a boundary between adjacent sub-pixels, covering a periphery of an upper surface of the anode electrode, and including a first bank on the anode electrode and a second bank on the first bank,
wherein the first bank includes:
an overlapping portion overlapping the second bank; and
an exposed portion exposed by the second bank, and
an outline of the exposed portion has a plurality of bent portions in a plan view.

21. The display device of claim 20, wherein the plurality of bent portions that are adjacent are spaced apart from each other in a plan view.

22. The display device of claim 20, wherein the first bank includes a black-based material, and the second bank includes a transparent-based material.

23. The display device of claim 20, wherein a pattern in which the plurality of bent portions of the first sub-pixel are disposed differs from a pattern in which the plurality of bent portions of the second sub-pixel are disposed.

24. The display device of claim 20, further comprising:
an organic layer disposed on the anode electrode and the bank and disposed across the plurality of sub-pixels;
a cathode electrode on the organic layer; and
a black matrix located at a boundary between the adjacent sub-pixels on the cathode electrode,
wherein a width of the black matrix is smaller than a width of the first bank, and an end of the black matrix is closer to the boundary between the adjacent sub-pixels than an end of the first bank.

25. A display device comprising:
a substrate including a display area including a plurality of sub-pixels, and a non-display area adjacent to the display area;
an anode electrode disposed in each of the plurality of sub-pixels on the substrate;
a bank disposed on the anode electrode, located at a boundary between adjacent sub-pixels, and covering a periphery of an upper surface of the anode electrode;
an organic layer disposed on the anode electrode and the bank and disposed across the plurality of sub-pixels; and
a protective layer disposed under the organic layer, and including a trench overlapping the bank and passing through the protective layer in a thickness direction.

26. The display device of claim 25, wherein the trench is configured to separate the organic layer disposed across the plurality of sub-pixels.
